(19) United States
(12) Patent Application Publication
(10) Pub. No.: US 2018/0206358 A1
(43) Pub. Date: Jul. 19, 2018

(54) Retainer for Electronic Modules

(71) Applicant: Pentair Technical Product Inc.., San Diego, CA (US)

(72) Inventor: Michael Joist, Gaggenau (DE)

(21) Appl. No.: 15/873,774

(22) Filed: Jan. 17, 2018

Related U.S. Application Data
(60) Provisional application No. 62/447,288, filed on Jan. 17, 2017.

(51) Int. Cl. H05K 7/14

(52) U.S. Cl. CPC H05K 7/1404; H05K 7/1442

(57) ABSTRACT

A retainer can be configured to secure an electronic module to a body. A wedge arrangement of the retainer can extend along a wedge axis and can include expansion wedges and actuation wedges. Brackets can be secured at least partly around the wedge arrangement. An actuator can compress the wedge arrangement along the wedge axis so that the actuation wedges urge the expansion wedges in opposite lateral directions, relative to the wedge axis, and the expansion wedges urge the brackets perpendicularly to the opposite lateral directions and the wedge axis.

### CROSS-REFERENCE TO RELATED APPLICATIONS

This application claims priority to U.S. Provisional Patent Application No. 62/447,288, titled “RETAINER FOR ELECTRONIC MODULES” and filed Jan. 17, 2017, the entirety of which is incorporated herein by reference.

### BACKGROUND

In different settings, it may be useful to secure electronic modules to other bodies. For example, it may be useful to secure a circuit card with respect to a cold plate, such that the card maintains a relatively fixed location when subjected to vibrations or other forces. Securing a circuit card to a cold plate may also support heat removal from the card, including via heat transfer from the card to the plate.

Conventional retainers for securing an electronic module to a body such as a cold plate can include sets of interleaved wedges having overlapping ramped ends. The wedges can be movably retained on a rail, which in turn can be fixed in place on the electronic module. A screw extending into the wedges can be tightened in order to compress the wedges along the rail, thereby increasing the amount of overlap of the ramped ends of the wedges and shortening the overall length of the retainer. Due to contact between the ramped ends of adjacent wedges, this collective shortening of the retainer, and the corresponding increased overlap of the wedges, can result in some of the wedges moving laterally outward away from the rail (e.g., by moving generally perpendicularly relative to an elongate aspect of the retainer). With sufficient tightening of the screw, these laterally moved wedges can be strongly urged against the retention body and thereby secure the electronic module to the relevant body.

### SUMMARY

Some embodiments of the invention provide a retainer for securing an electronic module to a body. The retainer can have an elongate direction and can include a wedge arrangement and an actuator. The wedge arrangement can be disposed along a wedge axis that extends in the elongate direction, and can include at least a first end wedge, a second end wedge, a first expansion wedge, and a second expansion wedge. The actuator can be configured to apply compressive force along the wedge axis to compress the wedge arrangement.

Each of the first and second end wedges can have a respective ramped portion. The first and second expansion wedges can be disposed on opposite sides of the wedge axis, and each of the first and second expansion wedges can include a respective set of two ramped portions. The compressive force can be transferred along the wedge arrangement via the ramped portions of the first and second end wedges and the first and second expansion wedges, the compressive force thereby urging the first and second expansion wedges laterally away from the wedge axis in two different directions.

Some embodiments of the invention provide a retainer for securing an electronic module to a body. The retainer can have an elongate direction and can include a first bracket, a second bracket, a wedge arrangement, and an actuator. The first bracket can include a first channel, and the second bracket can include a second channel. The wedge arrangement can be disposed at least partly within the first channel and the second channel, can extend along a wedge axis in the elongate direction. The wedge arrangement can include a first end wedge with a bidirectional ramp, a first expansion wedge with opposite ramped ends, a second expansion wedge with opposite ramped ends, and at least one of: a second end wedge with a bidirectional ramp, and a center wedge with a bidirectional ramp. The actuator can be configured to apply compressive force along the wedge axis to compress the wedge arrangement.

The first expansion wedge can be disposed on a first side of the wedge axis and the second expansion wedge can be disposed on a second side of the wedge axis. The compressive force can urge the opposite ramped ends of the first expansion wedge into, respectively, the bidirectional ramp of the first end wedge and the bidirectional ramp of the at least one of the second end wedge and the center wedge, and can urge the opposite ramped ends of the second expansion wedge into, respectively, the bidirectional ramp of the first end wedge and the bidirectional ramp of the at least one of the second end wedge and the center wedge. The compressive force can also urge the first bracket, via the first expansion wedge, in a first direction away from the wedge axis, and can urge the second bracket, via the second expansion wedge, in a second direction away from the wedge axis.

Some embodiments of the invention provide method of securing an electronic module to a body with a channel. The method can include disposing a retainer within the channel, with the retainer including a wedge arrangement that extends along a wedge axis. The wedge arrangement can include at least two expansion wedges disposed on opposite sides of the wedge axis, and actuation wedges configured as two or more of: a first end wedge, a second end wedge, and a center wedge. A compressive force can be applied to the wedge arrangement so that ramped surfaces of the expansion wedges are urged against ramped surfaces of the actuation wedges, with the expansion wedges being thereby urged in different lateral directions relative to the wedge axis to clamp the body within the channel.

Some embodiments of the invention provide a retainer configured to secure an electronic module within a channel. A wedge arrangement can extend along a wedge axis and includes a plurality of actuation wedges, a first expansion wedge, and a second expansion wedge. An actuator can be configured to compress the plurality of actuation wedges along the wedge axis. A first bracket and a second bracket can be secured at least partly around the wedge arrangement. The actuation wedges can be configured, when the actuation wedges are compressed along the wedge axis, to urge the first expansion wedge in a first expansion direction that is substantially perpendicular to the wedge axis, and to urge the second expansion wedge in a second expansion direction that is substantially opposite the first expansion direction. The first and second expansion wedges can be configured, when urged, respectively, in the first and second expansion directions, to collectively urge the first bracket in a first clamping direction that is substantially perpendicular to the first expansion direction and to the wedge axis, and to collectively urge the second bracket in a second clamping direction that is substantially opposite the first clamping direction, to secure the electronic module within the channel.

Some embodiments of the invention provide a retainer for securing an electronic module to a body. The retainer can have an elongate direction and can include a first bracket and a second bracket. A wedge arrangement can extends along a wedge axis in the elongate direction, can be at least partly surrounded by the first and second brackets, and can include a first actuation wedge, a second actuation wedge, a first expansion wedge with opposite ramped ends, and a second expansion wedge with opposite ramped ends. An actuator can be configured to apply compressive force along the wedge axis to compress the wedge arrangement along the wedge axis.

The first and second expansion wedges can be disposed between the first and second actuation wedges, on opposite sides of the wedge axis, with the opposite ramped ends of the first and second expansion wedge engaging, respectively, the first and second actuation wedges. The actuator and the wedge arrangement can be configured so that the compressive force urges the first and second actuation wedges into the opposite ramped ends of the first and second expansion wedges to move the first and second actuation wedges in opposite lateral directions away from the wedge axis. The wedge arrangement and the first and second brackets can be configured so that the lateral movement of the first and second actuation wedges away from the wedge axis urges the first and second brackets in opposite lateral directions away from the wedge axis, substantially perpendicularly to the lateral movement of the first and second actuation wedges away from the wedge axis.

Some embodiments of the invention provide a method of securing an electronic module to a body with a channel. A retainer can be disposed within the channel, the retainer including a wedge arrangement that extends along a wedge axis and at least two brackets that at least partly surround the wedge arrangement, and the wedge arrangement including at least two expansion wedges disposed on opposite sides of the wedge axis relative to each other, and actuation wedges configured as two or more of: a first end wedge, a second end wedge, and a center wedge. A compressive force can be applied to move the actuation wedges along the wedge axis, so that ramped surfaces of the actuation wedges are urged against ramped surfaces of the expansion wedges to urge the actuation wedges in first opposite lateral directions, relative to the wedge axis, the actuation wedges thereby urging the at least two brackets in second opposite lateral directions that are substantially perpendicular to the first opposite lateral directions, to clamp the body within the channel.

### BRIEF DESCRIPTION OF THE DRAWINGS

The accompanying drawings, which are incorporated in and form a part of this specification, illustrate embodiments of the invention and, together with the description, serve to explain the principles of embodiments of the invention:

FIG. 1 is an isometric view of a conventional retainer for securing a circuit board to a cold plate;

FIG. 2 is a top view of a conventional retainer, illustrating paths for conductive heat transfer through the conventional retainer, from a circuit board to a cold plate;

FIGS. 3A through 3F are isometric, front elevation, and top plan views of a retainer according to one embodiment of the invention, with the retainer in a relaxed configuration in FIGS. 3A, 3C, and 3E, and with the retainer in an expanded configuration in FIGS. 3B, 3D, and 3F;

FIGS. 4A through 4E are isometric, top plan, side elevation, and cross-sectional views of a bracket for the retainer of FIGS. 3A through 3F;

FIGS. 5A through 5E are isometric, top plan, side elevation, and cross-sectional views of another bracket for the retainer of FIGS. 3A through 3F;

FIGS. 6A through 6F are cross-sectional, rear and side elevation, top plan, and isometric views of an end wedge for the retainer of FIGS. 3A through 3F;

FIGS. 7A through 7E are isometric, side elevation, top plan, and front elevation views of another end wedge for the retainer of FIGS. 3A through 3F;

FIGS. 8A through 8D are side and front elevation, top plan, and isometric views of a center wedge for the retainer of FIGS. 3A through 3F;

FIGS. 9A through 9D are isometric, and side and front elevation views of an expansion wedge for the retainer of FIGS. 3A through 3F;

FIG. 9E is a front elevation view of the expansion wedge of FIGS. 9A through 9D, arranged with another substantially identical expansion wedge for installation in a retainer;

FIGS. 10A through 10E are rear, side, and front elevation, and isometric views of an end cover for the retainer of FIGS. 3A through 3F;

FIGS. 11A and 11B are isometric and side elevation partial views of a rod actuator for the retainer of FIGS. 3A through 3F;

FIG. 11C is an isometric partial view of the rod actuator of FIGS. 11A and 11B with a washer and c-clip;

FIGS. 12A and 12B are side elevation and isometric views of certain components of the retainer of FIGS. 3A through 3F with the retainer in the relaxed configuration;

FIGS. 13A and 13B are side elevation plan and isometric views of internal components of the retainer of FIGS. 3A through 3F with the retainer in an expanded configuration;

FIGS. 14A and 14B are top plan views of the retainer of FIGS. 3A through 3F in relaxed and expanded configurations, respectively, with the brackets of FIGS. 4A through 5E rendered transparently;

FIGS. 15A and 15B are side elevation views of the retainer of FIGS. 3A through 3F in relaxed and expanded configurations, respectively, with the brackets of FIGS. 4A through 5E rendered transparently;

FIG. 16A is a cross-sectional view of the retainer of FIGS. 3A through 3F in the relaxed configuration, taken along line 16-16 of FIG. 15A;

FIGS. 16B and 16C are cross-sectional views of the retainer of FIGS. 3A through 3F from a perspective similar to FIG. 16A, illustrating different degrees of expansion into the expanded configuration;

FIG. 17A is a cross-sectional view of the retainer of FIGS. 3A through 3F in the expanded configuration, similar to the view of FIG. 16B, in an example installation, with schematic illustrations of heat transfer from a circuit board to a cold plate through the retainer of FIGS. 3A through 3F;

FIG. 17B is a top plan view of the retainer of FIGS. 3A through 3F in the expanded configuration, in an example installation and, with schematic illustrations of heat transfer from a circuit board to a cold plate through the retainer of FIGS. 3A through 3F;

FIGS. 18A and 18B are cross-sectional top views of an example spring-biased configuration of the retainer of FIGS. 3A through 3F, in the relaxed and expanded configurations, respectively;

FIGS. 19A and 19B are cross-sectional side views of the example spring-biased configuration of FIGS. 18A and 18B, also in the relaxed and expanded configurations, respectively;

FIGS. 20A and 20B are isometric views of a retainer according to another embodiment of the invention;

FIG. 21A is an isometric view of the retainer of FIGS. 20A and 20B, with brackets of the retainer rendered transparently;

FIG. 21B is an isometric partial view of a rod actuator for use with the retainer of FIGS. 20A and 20B;

FIGS. 22A and 22B are isometric full and partial views, respectively, of a retainer according to yet another embodiment of the invention, with brackets of the retainer rendered transparently;

FIG. 23 is an exploded isometric view of a retainer according to still another embodiment of the invention;

FIG. 24A is an isometric partial view of a retainer according to a further embodiment of the invention;

FIG. 24B is an isometric partial view of a bracket for the retainer of FIG. 24A; and

FIG. 25 is an isometric partial view of a retainer according to yet a further embodiment of the invention.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

Unless otherwise specified or limited, the phrases “at least one of A, B, and C,” “one or more of A, B, and C,” and the like, are meant to indicate A, or B, or C, or any combination of A, B, and/or C, including combinations with multiple or single instances of A, B, and/or C. Likewise, unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

As used herein, unless otherwise specified or limited, the term “wedge” generally describes an arrangement in which a component or body includes a ramped surface. In this regard, a body or assembly configured as a “wedge” may also include certain non-ramped surfaces or shapes. For example, a body configured as an elongate wedge can have a curved or otherwise sloped surface at a first end and include other geometry at a second end.

As used herein in the context of elongate members or assemblies, unless otherwise specified, “lateral” and variations thereon generally indicates a direction that is substantially perpendicular to a direction in which the relevant member or assembly is elongate. Similarly, “longitudinal” generally indicates a direction that is substantially parallel to the direction in which the relevant member or assembly is elongate.

As used herein, unless otherwise specified or limited, the term “ramp” or “ramped” generally describes a surface that extends at an angle relative to a reference surface or feature. In some embodiments, a “ramp” or a “ramped” surface can include a planar ramp, a curving ramp, or both.

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown, but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

Generally, embodiments of the invention provide improved retainers for electronic modules, which can provide improved retention and heat transfer capabilities in comparison to conventional retainers. In some embodiments, a wedge arrangement is secured within at least two brackets. An actuator, such as a threaded rod, can be used (e.g., manually engaged) in order to compress the wedge arrangement in a first direction. As the wedge arrangement is compressed, the various wedges can interact so that certain of the wedges are moved in second directions different from the first direction, thereby causing the brackets to collectively expand in a third direction.

In some embodiments, a wedge arrangement can include one or more actuation wedges configured as one or more end wedges and/or center wedges, as well as one or more sets of at least two expansion wedges. Each set of the expansion wedges can include a first expansion wedge disposed at least partly to one side of a centerline and a second expansion wedge disposed at least partly to another side of the centerline (e.g., directly opposite the first expansion wedge). Longitudinal ends of the expansion wedges, the end wedge(s) and any center wedges can be ramped (e.g., chamfered) with generally complementary geometries configured to engage ramps of adjacent actuation (e.g., center or end) wedges. Likewise, each of certain actuation wedges, such as relevant end and center wedges, can include a respective bidirectional ramp to engage the ramped ends of adjacent expansion wedges.

As such a wedge arrangement is compressed in the longitudinal direction, the bidirectional ramps of relevant actuation wedges can be urged into ramped ends of adjacent sets of expansion wedges. The interaction of the various ramped ends can thereby cause the expansion wedges of a given set to move in opposite lateral directions, generally perpendicularly to the longitudinal direction. This expansion of the expansion wedges can, in turn, cause the bracket assembly to also expand generally perpendicularly to the longitudinal direction.

In some embodiments, brackets of a bracket assembly can be caused to expand via a lateral movement that is generally perpendicular to a lateral expansion movement of sets of expansion wedges. For example, ramped surfaces on the exterior of expansion wedges can engage ramped surfaces along internal channels of associated brackets, with each expansion wedge of a given set simultaneously engaging each bracket. As the expansion wedges expand laterally relative to a wedge axis, the ramped surfaces of the expansion wedges can bear on the corresponding ramped surfaces of the brackets to urge the brackets to expand laterally, relative to the wedge axis, via a movement that is perpendicular to the movement of the expansion wedges.

In some embodiments, multiple expansion wedges for an assembly can be formed to be substantially identical to each other, as can multiple actuation (e.g., center or end) wedges. Accordingly, through the use of a select number of actuation wedges and a corresponding number of sets of expansion wedges, a retainer of any variety of longitudinal lengths can be readily assembled.

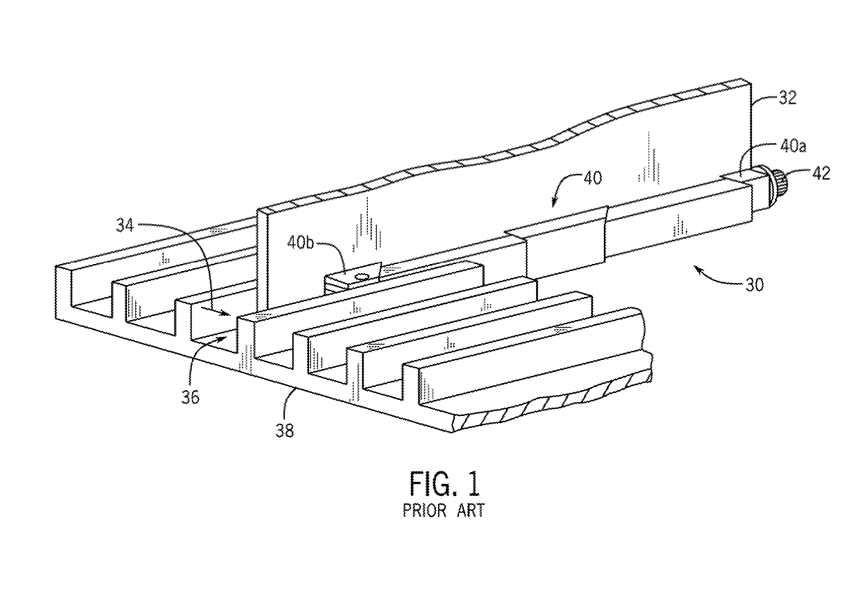

FIG. 1 illustrates a conventional retainer 30 for securing a circuit card 32 within a slot 36 on a cold plate 38 that defines a separation direction 34. An extended rail is secured to the card 32, and a set of wedges 40 with ramped ends are arranged along the rail. A screw 42 extends through the wedges and can be tightened in order to collectively compress the wedges 40 along the rail. As the wedges 40 are compressed together, contact between ramped ends of adjacent wedges causes two of the inner wedges to move laterally away from the rail, in the separation direction 34, and into contact with a side wall of the slot 36. With appropriate tightening of the screw 42, and the corresponding collective compression of the wedges 40, the contact of the inner wedges with the side wall of the slot 36 can secure the card 32 within the slot 36.

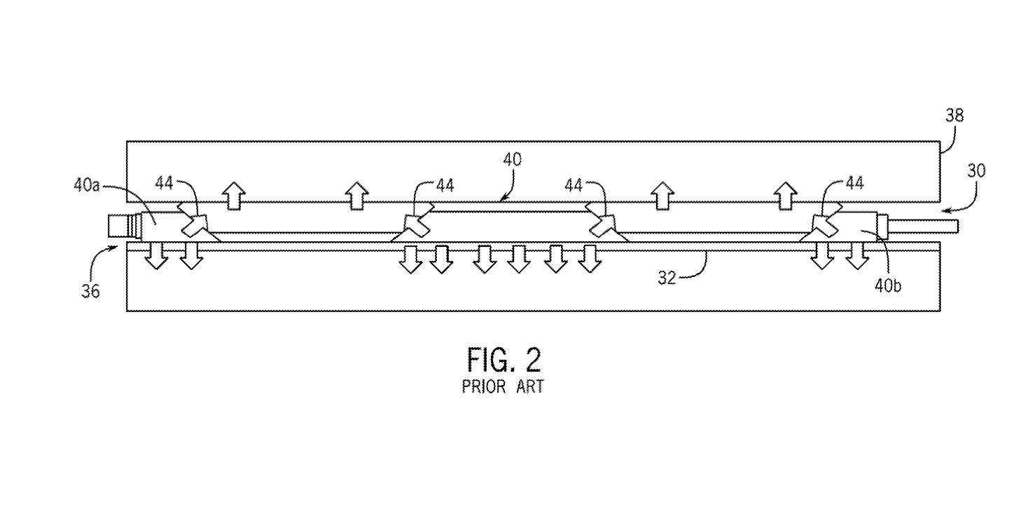

FIG. 2 illustrates paths for heat flow during use of the retainer 30, with the retainer 30 in an expanded configuration to secure the circuit card 32 to the cold plate 38. As illustrated by heat-transfer arrows 44, conductive heat transfer from the circuit card 32 through the retainer 30 is limited by the relatively small contact area between adjacent wedges 40. Accordingly, the retainer 30 may not provide particularly efficient heat transfer from the circuit card 32 to the cold plate 38. Further, the collective compression of wedges 40 between end wedges 40a and 40b, which may be anchored to the circuit card 32, can impose undesirable axial loading on the circuit card 32.

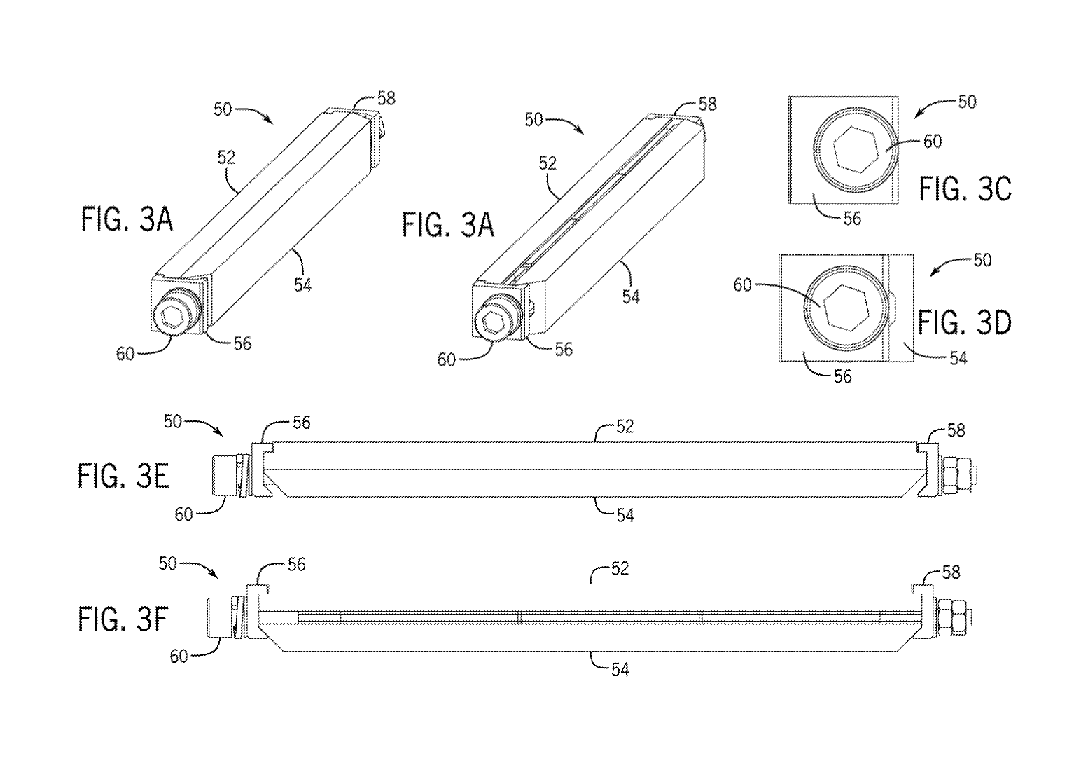

FIGS. 3A through 3F illustrate an embodiment of the invention configured to improve on certain aspects of conventional retainers such as the conventional retainer 30, as well as to provide various other benefits. In this regard, a retainer 50 generally includes a pair of external brackets 52 and 54, a set of covers 56 and 58, a rod actuator 60, and a set of internal wedges (not labeled or universally shown in FIGS. 3A through 3F). As illustrated in FIGS. 3A, 3C, and 3E, the brackets 52, 54 are relatively close together when the retainer 50 is in a relaxed configuration, thereby providing a relatively small lateral width for the retainer 50. As illustrated in FIGS. 3B, 3D, and 3F, the brackets 52, 54 are less close together when the retainer 50 is in an expanded configuration, thereby providing a relatively large lateral width for the retainer 50, and allowing the retainer 50 to secure an electronic module (e.g., a printed circuit board (“PCB”)) or other body to a desired structure. For example, the retainer 50 can be used to secure a PCB within channel on a cold frame, such as the slot 36 of FIG. 1.

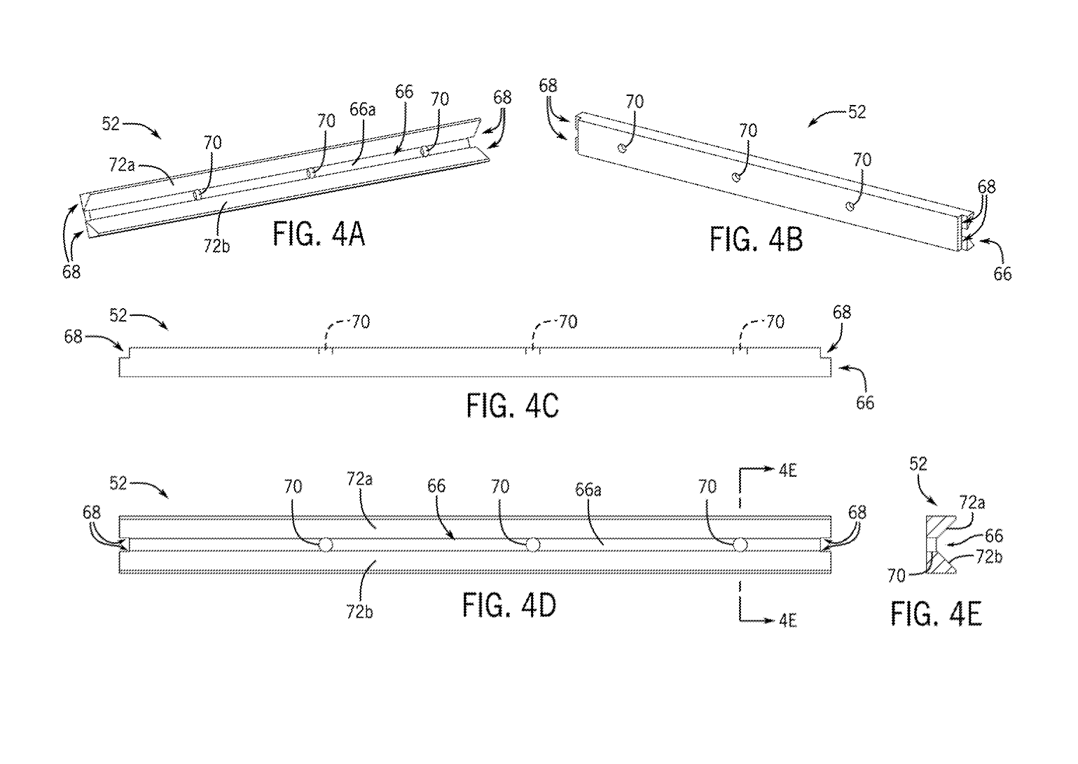

FIGS. 4A through 4E illustrate an example configuration of the bracket 52, for use as a mounting bracket to secure the retainer 50 to an electronic module. In the embodiment illustrated, the bracket 52 includes an elongate body of generally uniform cross section. An angled channel 66 extends along the elongate body, with a generally flat bottom 66a and ramped inner walls 72a and 72b. At opposite longitudinal ends, the bracket 52 includes shoulders 68, with the ramped inner walls 72a and 72b of the channel 66 extending longitudinally beyond the shoulders 68 to define a corresponding overhang. As illustrated, the bottom 66a of the channel 66 includes three threaded holes 70 to receive threaded fasteners for securing the bracket 52 to an electronic module. In other embodiments, other configurations are possible, including different numbers or locations of threaded or other fastener holes.

In some embodiments, the bracket 52 can be formed from aluminum. In some embodiments, the bracket 52 can be extruded and then machined (as needed). In some embodiments, the bracket 52 can be die cast or otherwise formed.

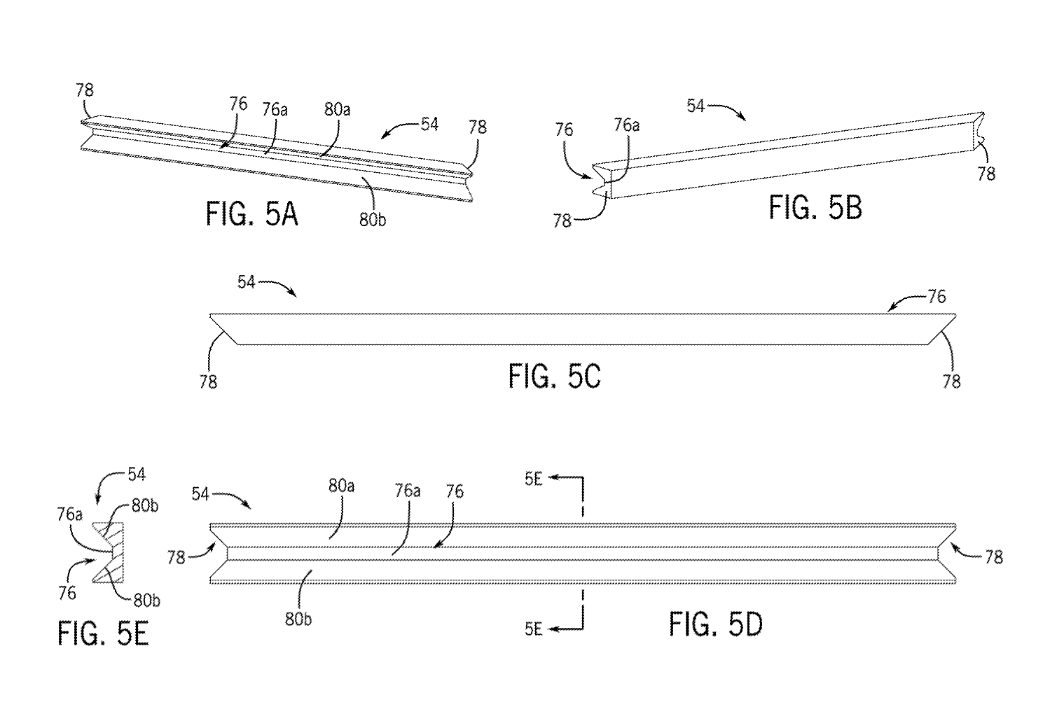

FIGS. 5A through 5E illustrate an example configuration of the bracket 54, for use as an expansion bracket to secure the retainer 50 and an associated electronic module to another structure. In the embodiment illustrated, the bracket 54 includes an elongate body with an angled channel 76. The angled channel 76 includes a generally flat bottom 76a and ramped side walls 80a and 80b that are generally similar, respectively, to the flat bottom 66a and ramped inner walls 72a and 72b of the bracket 52 (see, e.g., FIG. 4A). At opposite longitudinal ends, the bracket 54 includes ramped surfaces 78 sloping longitudinally outwardly, away from the bottom 76a of the channel 76, along the entire thickness of the bracket 54.

In some embodiments, the bracket 54 can be formed from aluminum. In some embodiments, the bracket 54 can be extruded and then machined (as needed). In some embodiments, the bracket 54 can be die cast or otherwise formed. In some embodiments, the bracket 54 can be formed from the same starting extrusion (or other body) as the bracket 52, with the brackets 52 and 54 being finished (e.g., machined) differently to provide the respective unique geometries of the brackets 52 and 54 as illustrated.

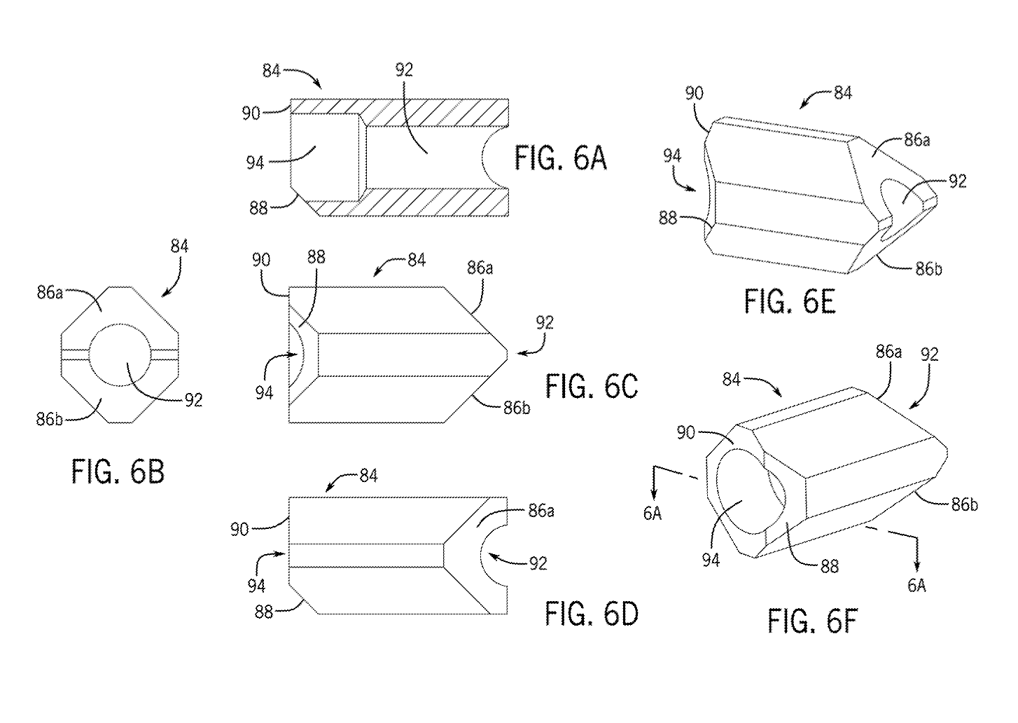

FIGS. 6A through 6F illustrate an embodiment of an actuation wedge for use with a wedge arrangement of the retainer 50, configured as an end wedge 84. In the embodiment illustrated, the end wedge 84 includes a generally rectangular (e.g., square) cross-sectional profile, with chamfered corners (see, e.g., FIG. 6B). One longitudinal end of the end wedge 84 includes a bidirectional ramp with ramped surfaces 86a and 86b that both slope outwardly from a centerline of the associated end of the end wedge 84, from a perspective moving from the bidirectional ramp towards an opposite longitudinal end of the end wedge 84. At the longitudinal end of the end wedge 84 opposite the bidirectional ramp, the end wedge 84 further includes a relatively large chamfer 88 that angles away from a generally flat end wall 90.

Generally, a bore 92 extends into the end wedge 84. In the embodiment illustrated, the bore 92 is a non-threaded bore that extends fully through the end wedge 84 and includes a countersunk portion 94 opposite the ramped surfaces 86a and 86b. In other embodiments, other configurations are possible. For example, part or all of the bore 92 can be threaded, the countersunk portion 94 can be differently configured or excluded entirely, the bore 92 can extend only partly through the end wedge 84, the bore 92 can be configured to receive a threaded or other insert (e.g., a thread-in insert or a press-fit insert), and so on. In some embodiments, a bore similar to the bore 92 may not be provided (e.g., no bore may extend into the end wedge 84).

In some embodiments, the end wedge 84 can be formed from aluminum. In some embodiments, the end wedge 84 can be extruded and then machined (as needed). In some embodiments, the end wedge 84 can be die cast or otherwise formed.

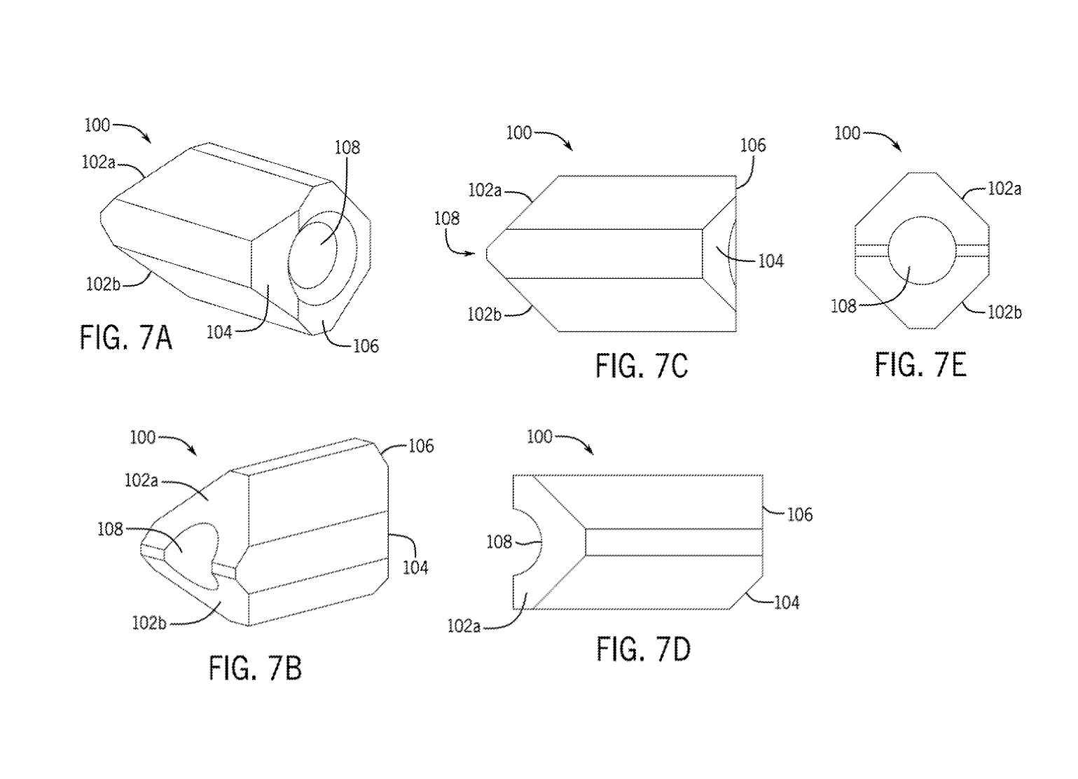

FIGS. 7A through 7E illustrate another embodiment of an actuation wedge for use with a wedge arrangement of the retainer 50, configured as another end wedge 100. In the embodiment illustrated, similarly to the end wedge 84 (see FIGS. 6A through 6F) the end wedge 100 includes a generally rectangular (e.g., square) cross-sectional profile, with chamfered corners (see, e.g., FIG. 7E). One longitudinal end of the end wedge 100 includes a bidirectional ramp with ramped surfaces 102a and 102b that both slope outwardly from a centerline of the associated end of the end wedge 100, from a perspective moving from the bidirectional ramp towards an opposite longitudinal end of the end wedge 100. At the longitudinal end of the end wedge 100 opposite the bidirectional ramp, the end wedge 100 includes a pair of relatively small chamfers 104 that angle away from a generally flat end wall 106.

Generally, a bore 108 extends into the end wedge 100. In the embodiment illustrated, the bore 108 is a threaded bore that extends fully through the end wedge 100 with a generally constant internal diameter (threading not shown in FIGS. 7A through 7E). In other embodiments, other configurations are possible. For example, part or all of the bore 108 may not be threaded, a countersunk portion can be included (e.g., similar to the countersunk portion 94 illustrated in FIGS. 6A through 6F), the bore 92 can extend only partly through the end wedge 100, the bore 108 can be configured to receive a threaded or other insert (e.g., a thread-in insert or a press-fit insert), and so on. In some embodiments, a bore similar to the bore 108 may not be provided (e.g., no bore may extend into the end wedge 100).

In some embodiments, the end wedge 100 can be formed from aluminum. In some embodiments, the end wedge 100 can be extruded and then machined (as needed). In some embodiments, the end wedge 100 can be die cast or otherwise formed. In some embodiments, the end wedge 100 can be formed from the same starting extrusion (or other body) as the end wedge 84, with the end wedges 84 and 100 being finished (e.g., machined) differently to provide their respective unique geometries.

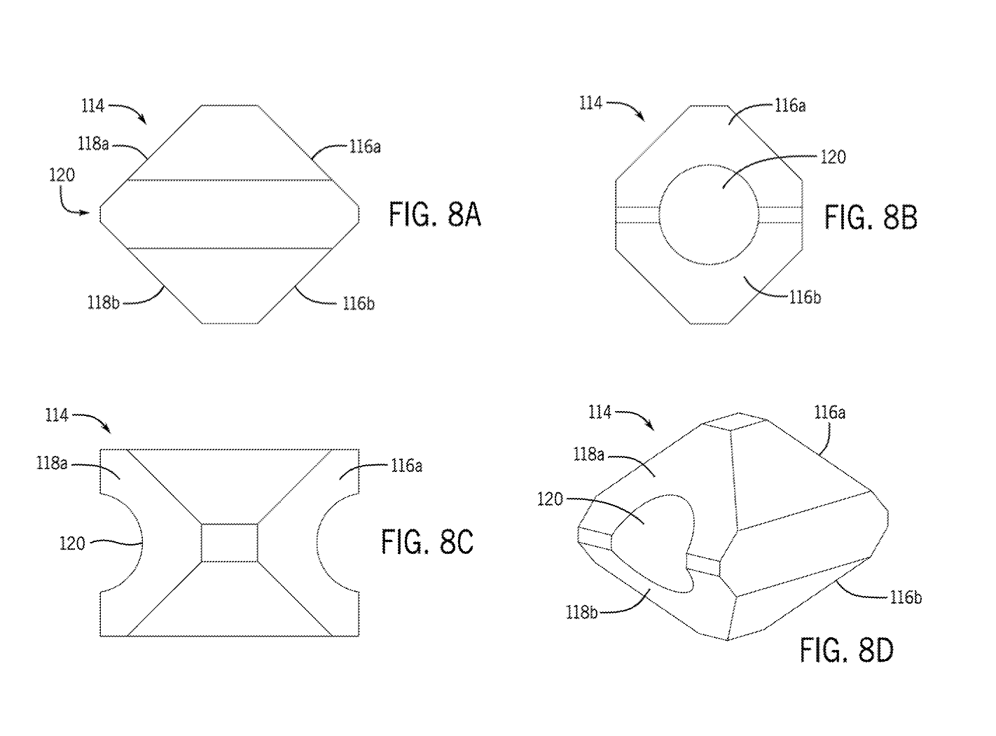

FIGS. 8A through 8D illustrate another embodiment of an actuation wedge for use with a wedge arrangement of the retainer 50, configured as a center wedge 114. In the embodiment illustrated, the center wedge 114 includes a generally rectangular (e.g., square) cross-sectional profile, with chamfered corners (see, e.g., FIG. 8B). Both longitudinal ends of the center wedge 114 include bidirectional ramps with respective ramped surfaces 116a, 116b, 118a, and 118b, all of which slope laterally outward from a centerline of the associated end of the center wedge 114, from a perspective moving from the bidirectional ramps towards a center of the body of the center wedge 114.

Generally, a bore 120 extends into the center wedge 114. In the embodiment illustrated, the bore 120 is a non-threaded bore that extends fully through the center wedge 114 with a generally constant internal diameter. In other embodiments, other configurations are possible. For example, part or all of the bore 120 may be threaded, a countersunk portion can be included (e.g., similar to the countersunk portion 94 illustrated in FIGS. 6A through 6F), the bore 120 can extend only partly through the center wedge 114, the bore 120 can be configured to receive a threaded insert (e.g., a thread-in insert or a press-fit insert), and so on. In some embodiments, a bore similar to the bore 120 may not be provided (e.g., no bore may extend into the center wedge 114)

In some embodiments, the center wedge 114 can be formed from aluminum. In some embodiments, the center wedge 114 can be extruded and then machined (as needed). In some embodiments, the center wedge 114 can be die cast or otherwise formed. In some embodiments, the center wedge 114 can be formed from the same starting extrusion (or other body) as one or both of the end wedges 84 and 100 with the various wedges 84, 100, and 114 being finished (e.g., machined) differently to provide their respective unique geometries.

The term “center,” as used herein with regard to “center wedges,” does not necessarily indicate that center wedges are disposed (or necessarily configured to be disposed) at a geometric center of an assembly or set of components. Rather, the term is intended to indicate a position that is generally between certain other components. For example, in some of the embodiments discussed herein, a center wedge is configured to be disposed generally between two end wedges (or other components of a relevant retainer).

In the embodiments illustrated in FIGS. 6A through 8D, the wedges 84, 100, and 114 are configured with generally similar cross-sectional profiles and with ramped ends that exhibit congruent or complimentary ramp geometry relative to a common longitudinal reference. As also discussed below, this can allow for relatively smooth and useful assembly and operation of the retainer 50. In other embodiments, however, other configurations may be possible.

Likewise, in the embodiments illustrated in FIGS. 6A through 8A, the wedges 84, 100, and 114 include bores 92, 108, and 120 with generally similar diameter, such that a rod of generally constant diameter can be extended (e.g., stabbed or threaded) into and through each of the wedges 84, 100, 114 in series. In other embodiments, other configurations are possible.

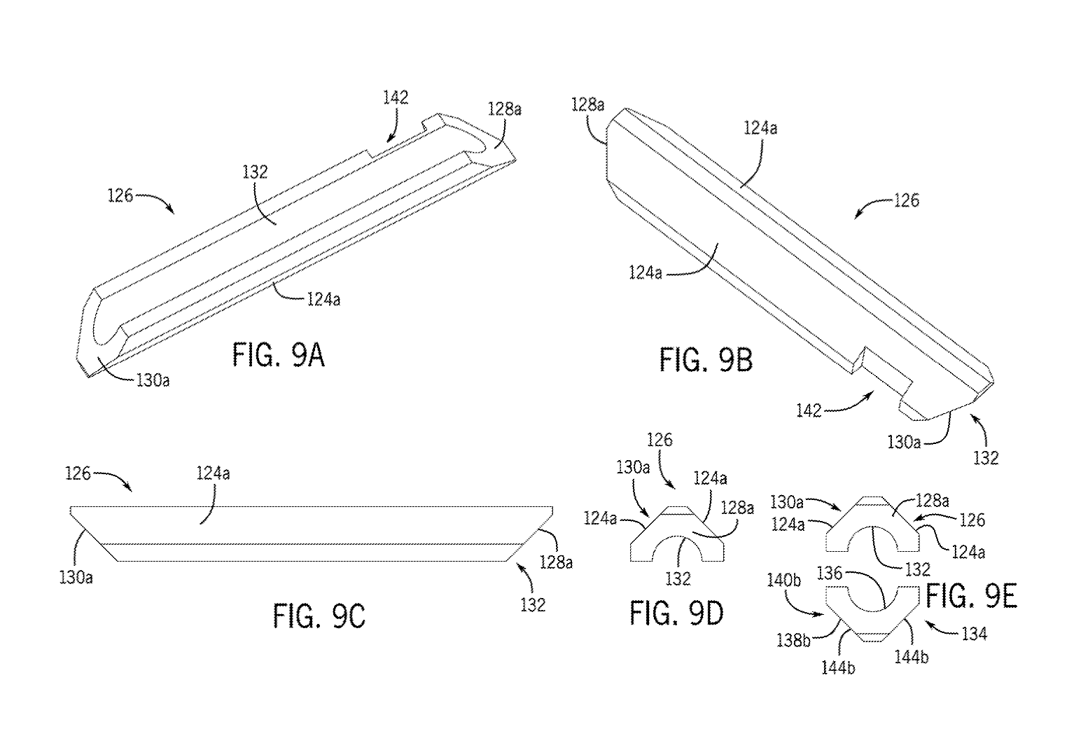

FIGS. 9A through 9D illustrate another embodiment of a wedge for use with a wedge arrangement of the retainer 50, configured as an expansion wedge 126 with ramped outer surfaces 124a. In the embodiment illustrated, the expansion wedge 126 includes a generally triangular (e.g., isosceles) cross-sectional profile, with chamfered corners (see, e.g., FIG. 9D). The longitudinal ends of the expansion wedge 126 include respective ramps with ramped surfaces 128a and 130a, each of which slopes laterally inward from a base portion of the expansion wedge 126, from a perspective moving from the relevant ramp towards a longitudinal center of the expansion wedge 126.

As needed, including to provide clearance for a rod actuator, a groove or other recess, such as a half bore 132, can extend into the expansion wedge 126. In the embodiment illustrated, the half bore 132 is configured as a non-threaded semi-circular channel that extends fully along the base of the expansion wedge 126 with a generally constant internal diameter. In other embodiments, other configurations are possible. For example, part or all of the half bore 132 (or another groove or recess) may be threaded, a countersunk portion can be included (e.g., similar to the countersunk portion 94 illustrated in FIGS. 6A through 6F), the half bore 132 can extend longitudinally only partly through the expansion wedge 126, the half bore 132 can be configured to receive an insert, and so on. In some embodiments, a feature similar to the half bore 132 may not be provided (e.g., no similar bore, or other groove or recess, may extend into the expansion wedge 126).

As illustrated in FIG. 9E, the expansion wedge 126 is configured for use in combination with a second expansion wedge 134. In some embodiments, the two expansion wedges 126 and 134 can be substantially identical, with the expansion wedge 134 including a half bore 136, two ramped end surfaces 138b and 140b, and ramped outer surfaces 144b that are similar to the half bore 132, the ramped end surfaces 128a and 130a, and the ramped outer surfaces 124a. The expansion wedges 126 and 134 can be arranged for use with their bases generally adjacent to each other, so that the half bores 132 and 136 are generally aligned to approximate a complete, circular bore through the set of the two wedges 126 and 134. This may, for example, provide clearance for an extended rod actuator or other component. Thus arranged, the ramped surfaces 128a and 138b are also generally aligned, as are the ramped surfaces 130a and 140b. Accordingly, the respective pairs of the ramped surfaces 128a, 138b, 130a, and 140b form angled cavities with profiles that are generally complementary to the bidirectional angled protrusions formed by the ramped surfaces 86a and 86b, 102a and 102b, 116a and 116b, and/or 118a and 118b of the end and center wedges 84, 100, and 114 (see FIGS. 6A through 8D), respectively.

In some embodiments, a wedge of a wedge arrangement can include further recesses, such as a right-angle cut-out 142 included in the illustrated embodiment of the expansion wedge 126. This can be useful, for example, to provide clearance for other components of an assembly. In some embodiments, different numbers of recesses (including no recesses), or recesses with different geometries, can be provided.

In some embodiments, the expansion wedge 126 can be formed from aluminum. In some embodiments, the expansion wedge 126 can be extruded and then machined (as needed). In some embodiments, the expansion wedge 126 can be die cast or otherwise formed.

Generally, as also discussed below, interaction of expansion wedges (e.g., the expansion wedges 126 and 134) with various combinations of end and center wedges (e.g., the end wedges 84 and 100 and the center wedge 114) can cause the expansion wedges to expand laterally away from a relevant wedge axis. Accordingly, various end and center wedges configured to actuate expansion of the expansion wedges (e.g., the end wedges 84 and 100 and the center wedge 114) can be generally considered to be “actuation” wedges.

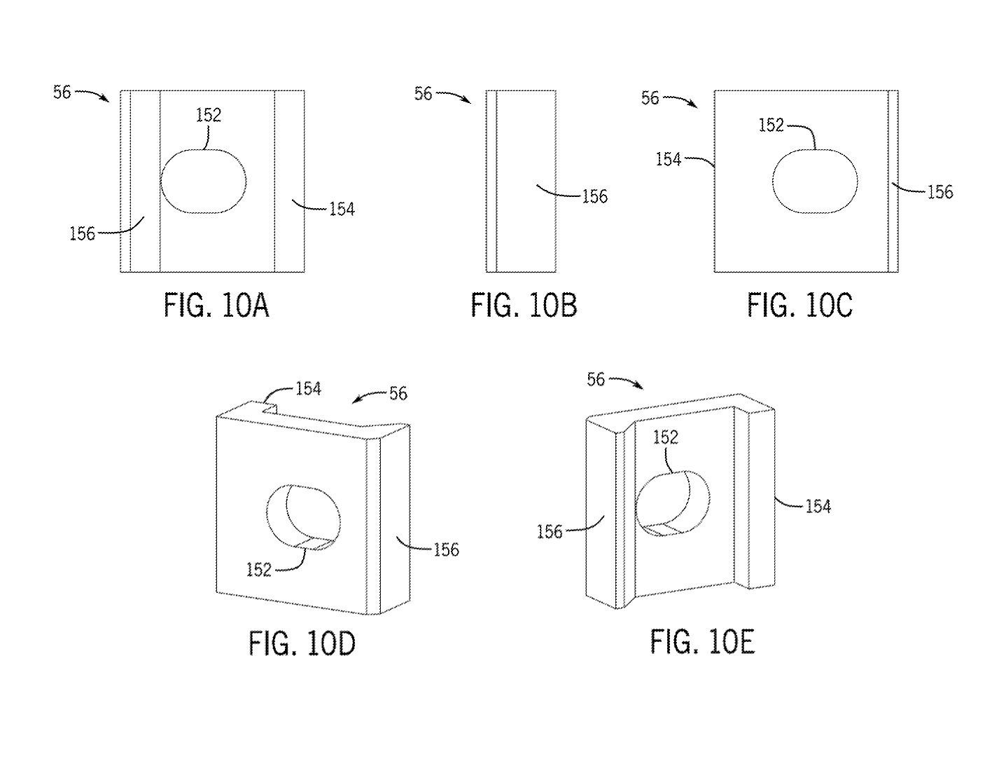

FIGS. 10A through 10E illustrate an example configuration of the cover 56. In the embodiment illustrated, the cover 56 includes a generally rectangular (e.g., square) body with an elongate, rounded opening 152. Towards one elongate end of the opening 152, the end cover 56 includes a square-shouldered flange 154. Towards an opposite elongate end of the opening 152, the end cover 56 includes a chamfered flange 156.

In some embodiments, the cover 56 can be formed from aluminum. In some embodiments, the cover 56 can be extruded and then machined (as needed). In some embodiments, the cover 56 can be die cast or otherwise formed. In some embodiments, the cover 58 (see, e.g., FIGS. 3E and 3F) can be formed to be substantially identical to the cover 56. In some embodiments, either of the covers 56 and 58 can be configured differently, including with different or no openings, different or no flanges, and so on.

The retainer 50 can be actuated in various ways. For example, in some embodiments, a cam and lever (not shown) or other similar mechanism can be provided, so that actuating the cam with the lever causes the wedge arrangement of the retainer 50 to be compressed or relaxed. In some embodiments, a rod actuator can be used, with rotation of a rod included in the rod actuator causing compression or relaxation of the relevant wedge arrangement.

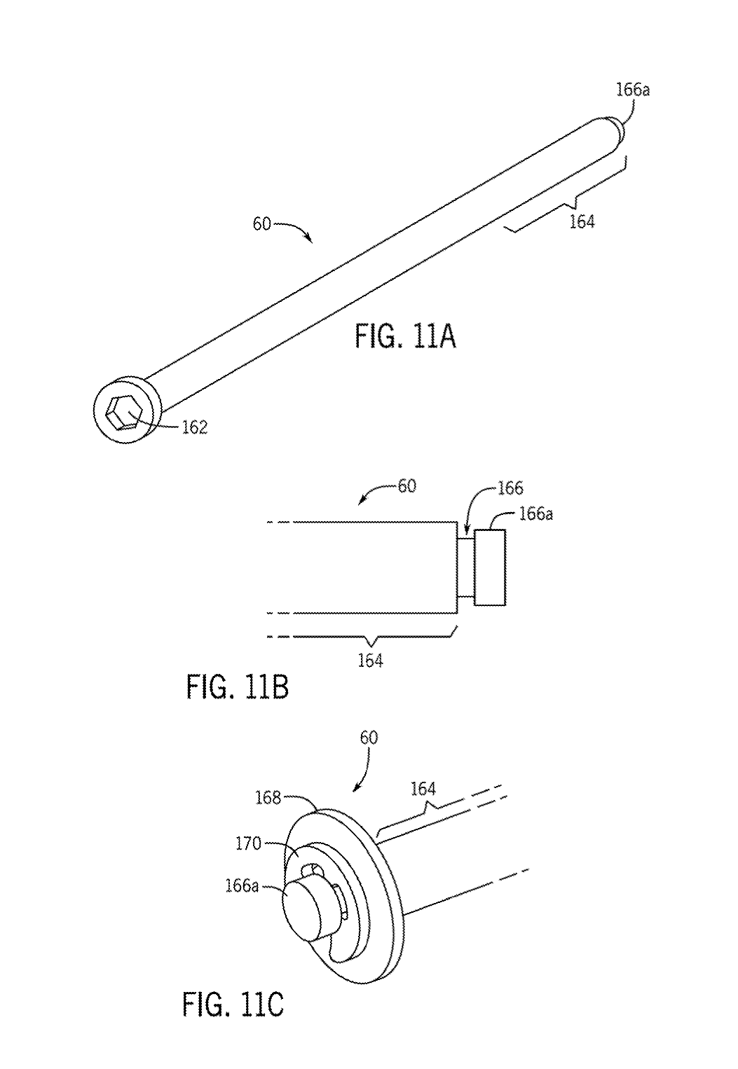

As illustrated in FIG. 11A, some embodiments of the rod actuator 60 for the retainer 50 can include a single elongate rod, which can extend over a full length of the retainer 50 (see, e.g., FIGS. 3A through 3F). At a first end, the rod actuator 60 includes an engagement feature, configured in the embodiment illustrated as a socket 162 for engagement with a hexagonal driver. At a second end as illustrated in FIG. 11B, the rod actuator 60 includes a threaded portion 164, an annular groove 166, and a reduced diameter portion 166a. The groove 166 can be used, for example, to receive and hold a washer 168 and c-clip 170, as illustrated in FIG. 1I C.

In other embodiments, other configurations of a rod actuator can be used. For example, in some embodiments, a rod actuator can be long enough only to extend partly into or partly through an associated retainer, or a wedge arrangement thereof. In some embodiments, one or more parts (e.g., one end) of a rod actuator can be threaded. In some embodiments, a rod actuator can include multiple rods, such as a first short rod at one end of a retainer and a second short rod at another end of the retainer.

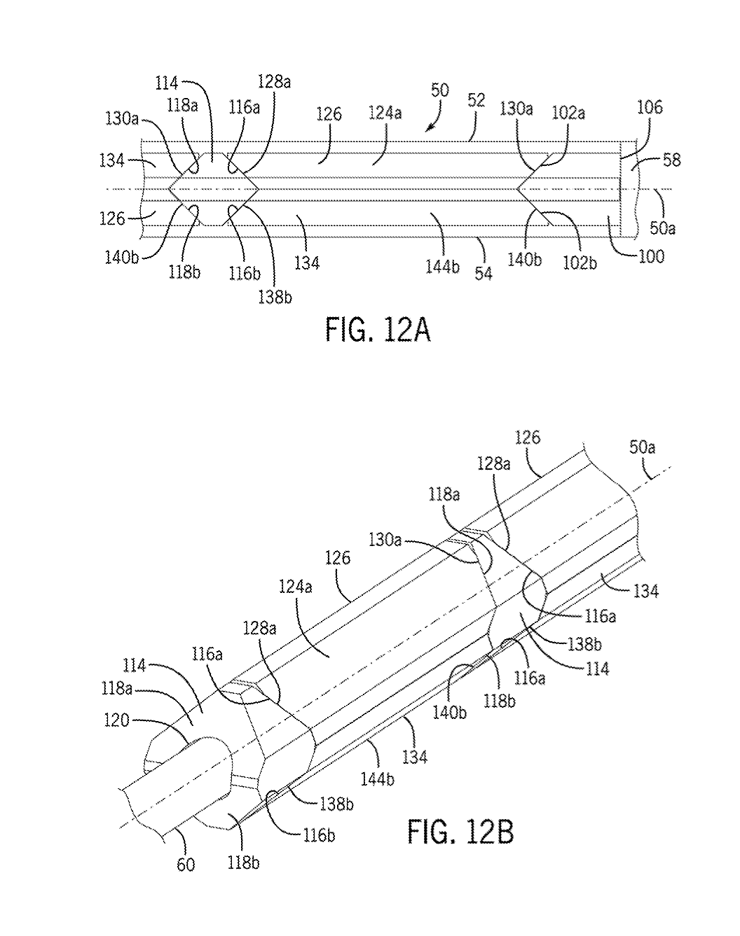

FIGS. 12A and 12B illustrate an example configuration of the wedge arrangement of the retainer 50, with the retainer 50 in a relaxed configuration. In particular, FIG. 12A illustrates an end portion of the wedge arrangement and FIG. 12B illustrates a center portion of the wedge arrangement, in each case with the brackets 52 and 54 removed.

Generally, the wedge arrangement is disposed (and extends) along a wedge axis, such as a wedge axis 50a illustrated in FIGS. 12A and 12B. In the embodiment illustrated, the wedge axis 50a extends along a centerline of the wedge arrangement, and of the retainer 50 generally. In other embodiments, a wedge axis may not necessarily coincide with such a centerline. Likewise, in the embodiment illustrated, the wedge axis 50a also generally coincides with an axis of symmetry of the wedge arrangement and, to a certain extent, the retainer 50. In other embodiments, different configurations are possible.

As illustrated in FIG. 12A, one end of the wedge arrangement is capped and contained by the cover 58, with the end wall 106 of the end wedge 100 seated against the cover 58. As appropriate, the rod actuator 60 (not shown in FIG. 12A) can be threaded into the bore 108 (not shown in FIG. 12A) of the end wedge 100, and can potentially extend longitudinally beyond the cover 58 (e.g., to the right in FIG. 12A).

The rod actuator 60 also extends between a pair of the expansion wedges 126 and 134, with expansion wedges 126 and 134 aligned with each other on opposite sides of the wedge axis 50a, and with the ramped surfaces 130a and 140b at one end of the expansion wedges 126 and 134 seated, respectively, against the ramped surfaces 102a and 102b of the end wedge 100. Similarly, as also illustrated in FIG. 12B, the rod actuator 60 extends through an instance of the center wedge 114, with the ramped surfaces 116a and 116b of the center wedge 114 seated against the other ramped surfaces 128a and 138b of the expansion wedges 126 and 134.

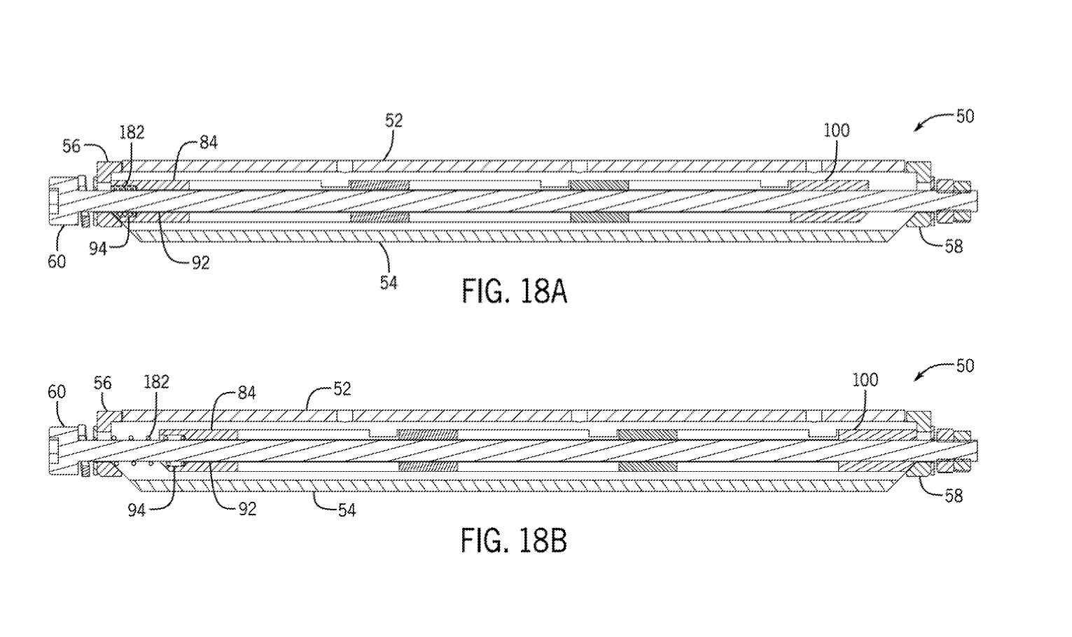

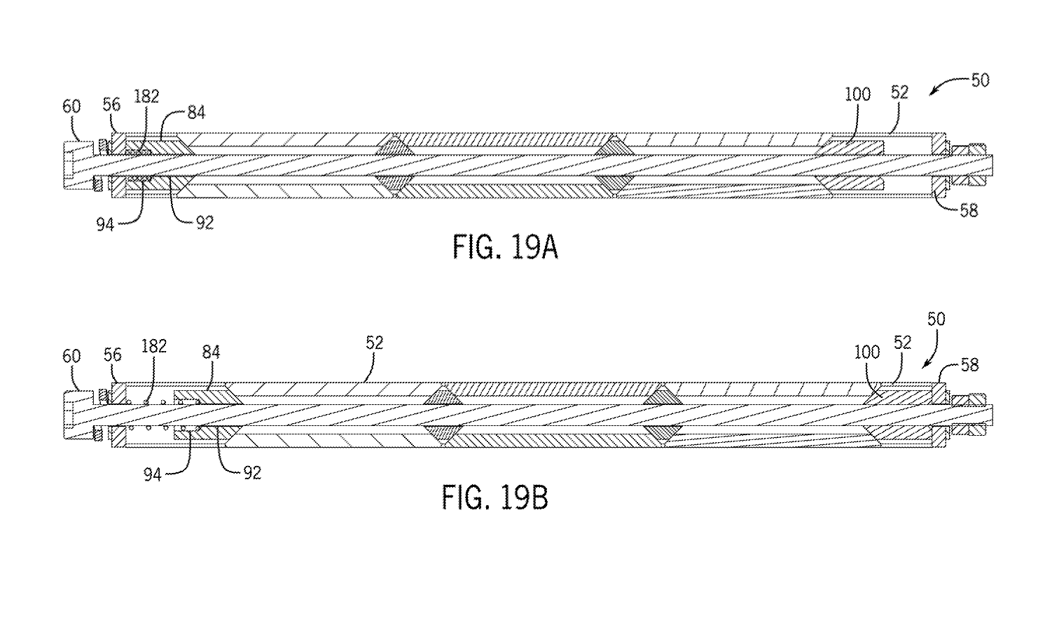

As illustrated in FIGS. 18A through 19B, the rod actuator 60 can also extend through the end wedge 84, with the ramped surfaces 86a and 86b of the end wedge 84 (see, e.g., FIGS. 6A through 6F) and the ramped surfaces 116a and 116b of the various center wedges 114 (see, e.g., FIGS. 8A through 8D) bearing on the ramped surfaces 128a and 138b of adjacent sets of the expansion wedges 126 and 134 (see, e.g., FIGS. 9A through 9E).

In different arrangements, as partially illustrated in both FIGS. 12A and 12B, any number of sets of the center wedges 114 and the expansion wedges 126 and 134 can be similarly arranged between sets of the end wedges 84 and 100, with the “a” and “b” ramped surfaces of the various center wedges 114 and/or end wedges 84 and 100 seated against the “a” and “b” ramped surfaces of the adjacent expansion wedges 126 and 134, respectively. In this way, for example, a retainer of any desired length can be provided, with a total length partly determined by the collective longitudinal length of the particular wedge arrangement selected. In some embodiments, only two end wedges and two expansion wedges (e.g., the end wedges 84 and 100 and the expansion wedges 126 and 134) can be used, with no center wedges.

In the embodiment of FIGS. 12A and 12B, multiple, substantially identical instances of the expansion wedges 126 and 134 and the center wedge 114 are used, with sets of the wedges 114, 126 and 134 arranged in series along the length of the relevant retainer. In some embodiments, other arrangements are possible. For example, different number, types, or arrangements of expansion wedges and center wedges can be used.

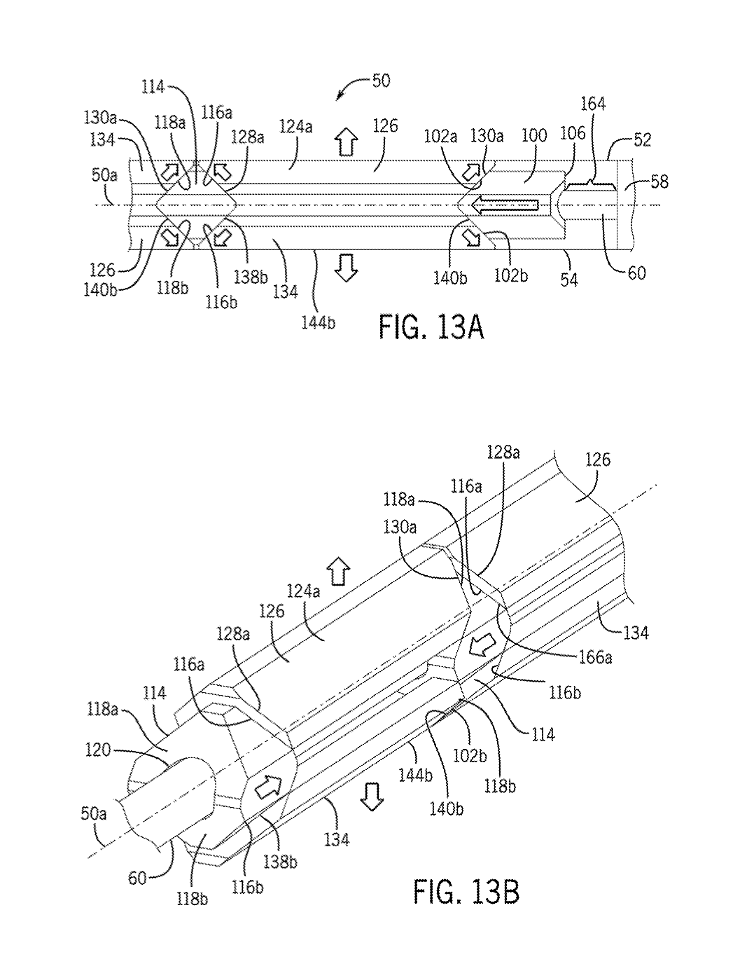

FIGS. 13A and 13B illustrate the wedge arrangement of the retainer 50 similarly to FIGS. 12A and 12B, but with the retainer 50 in an expanded configuration. As illustrated in FIG. 13A, when the rod actuator 60 is rotated in a “tightening” direction (e.g., with a right-hand rotation), the rotation of the rod actuator 60 moves the end wedge 100 longitudinally along the threaded portion 165 of the rod actuator 60, in a compressive direction (e.g., away from the cover 58, in the embodiment illustrated). This movement of the end wedge 100 urges the ramped surfaces 102a and 102b of the end wedge 100 against the corresponding ramped surfaces 130a and 140b of the adjacent set of the expansion wedges 126 and 134. Correspondingly, as also illustrated in FIG. 13B, this movement of the end wedge 100 also urges the ramped surfaces 128a and 138b of the expansion wedges 126 and 134 against the corresponding ramped surfaces 116a and 116b of the adjacent center wedge 114. Further, similar compression occurs similarly along the length of the wedge arrangement, with “a” and “b” ramped surfaces, respectively, of any other adjacent sets of the wedges 114, 126, and 134 being similarly urged against each other.

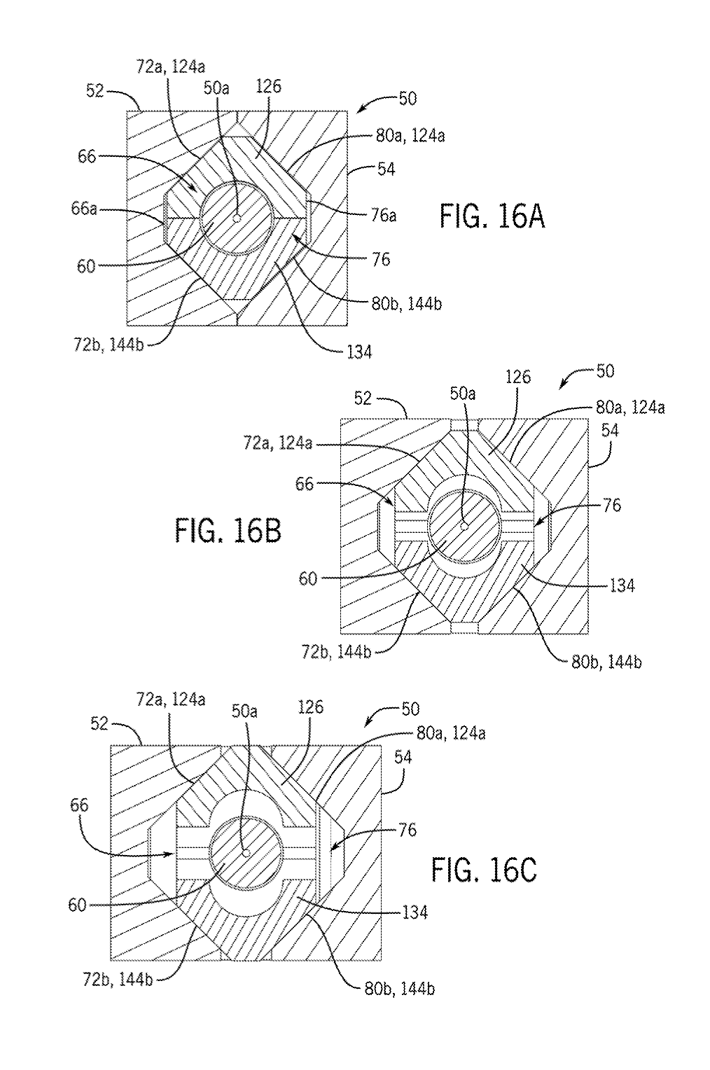

Due to the configuration of the various ramped surfaces of the various wedges (e.g., the ramped surfaces 128a, 138b, 116a, 116b, and so on), actuation of the rod actuator 60 to compress the wedge arrangement longitudinally along the length of the retainer 50 and the wedge axis 50a urges the various expansion wedges 126 and 134 to move laterally (e.g., radially), and in generally opposite directions, away from the rod actuator 60 and the wedge axis 50a. Further, because the brackets 52 and 54 are disposed to surround the wedge arrangement (see, e.g., FIGS. 16A through 16C), with the wedge arrangement engaged with internal walls of the angled channels 66 and 76, lateral movement of the expansion wedges 126 and 134 causes the brackets 52 and 54 also to move laterally (e.g., radially) away from the rod actuator 60.

Further, in the embodiment illustrated, rather than moving the brackets 52 and 54 in parallel with the expansion wedges 126 and 134, the expansion of the wedges 126 and 134 causes the brackets 52 and 54 to expand in directions that are generally perpendicular to the expansion directions of the expansion wedges 126 and 134. For example, as illustrated in FIGS. 16A through 16C, as the expansion wedges 126 and 134 are expanded vertically (from the perspective of FIGS. 16A through 16C), one set of the outer ramped surfaces 124a and 144b of the expansion wedges 126 and 134 simultaneously engage the channel inner walls 72a and 72b to urge the bracket 52 to move horizontally (from the perspective of FIGS. 16A through 16C). Similarly, another set of the outer ramped surfaces 124a and 144b of the expansion wedges 126 and 134 simultaneously engage the channel inner walls 80a and 80b to urge the bracket 54 to move horizontally in an opposite direction (from the perspective of FIGS. 16A through 16C).

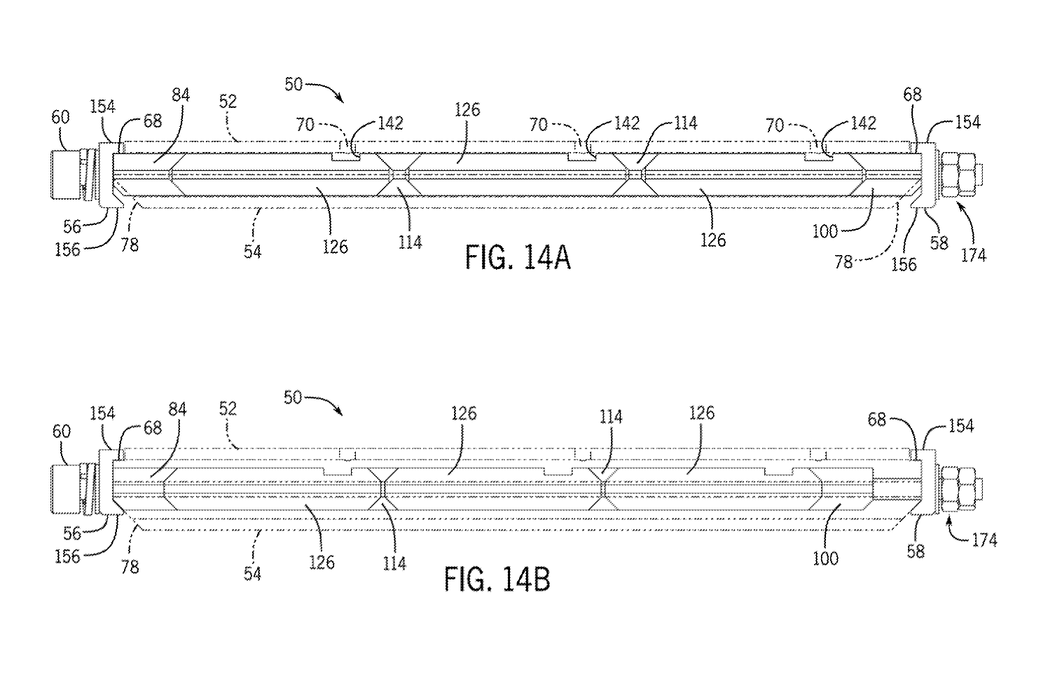

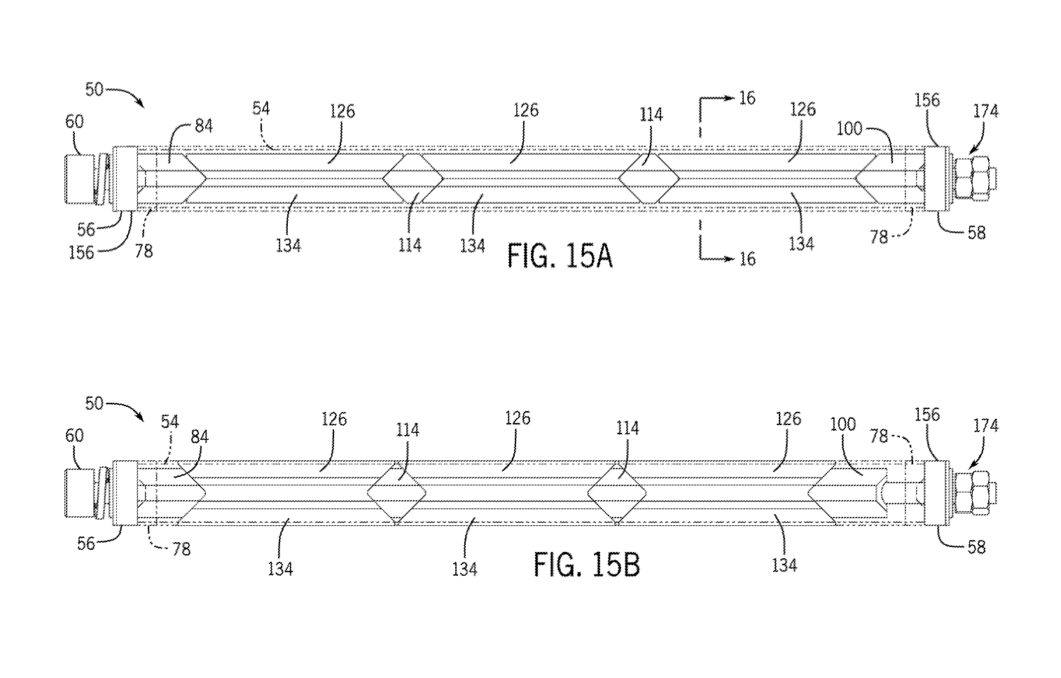

Thus, actuation of the rod actuator 60 to generally compress the wedge assembly longitudinally can move expand the retainer 50 laterally from the relaxed configuration (see FIGS. 14A and 15A) to the expanded configuration (see FIGS. 14B and 15B). AS also noted above, this can be useful, for example, so that the brackets 52 and 54 can compressively secure an electronic module (e.g., a PCB) within a channel.

In general, discussion herein of movement of certain components is intended to indicate relative movement, rather than absolute movement. For example, in some arrangements, as noted above, the bracket 52 can be secured to a PCB. With the PCB located against a wall of a slot of a cold plate, the bracket 52 may accordingly not be free to move relative to the channel even as the wedge arrangement expands. Rather, lateral expansion of the expansion wedges 126 and 134 may urge the bracket 52 firmly into the PCB and the slot wall without moving the bracket 52 in an absolute sense, with the wedge arrangement and the wedge axis 50a instead being moved laterally relative to the bracket 52. Although the bracket 52 may not absolutely move in such an arrangement, the bracket 52 may still be considered as moving laterally, relative to the wedge axis 50a. Similar considerations may also apply to other components of the retainer 50, or to components of other embodiments of the invention.

FIGS. 14A through 15B illustrate an embodiment of the retainer 50 in which a pair of nuts 174 are threaded onto the rod actuator 60, with a spring washer between the nuts 174 and the cover 58, to hold the assembly together. In other embodiments, other configurations are possible. For example, in some embodiments, an actuator with the grooved configuration illustrated in FIGS. 11B and 11C can be used, such that the nuts 174 may not be included.

As also illustrated in FIG. 14A, in some embodiments, the cut-outs 142 on the various expansion wedges 126 can be configured to align with the threaded holes 70 in the bracket 52 when the retainer 50 is in the fully relaxed configuration. This can be useful, for example, in order to provide clearance for fasteners extending through the holes 70. In some embodiments, the cut-outs 142 (or other recesses) can be excluded entirely, or can be configured differently, as may be useful to provide clearance for other features of the retainer 50.

As also illustrated in FIGS. 14A through 15B, when the retainer 50 is fully assembled, the square flanges 154 of the covers 56 and 58 are generally seated against the shoulders 68 of the bracket 52, and the chamfered flanges 156 of the covers 56 and 58 are generally aligned to face the ramped surfaces 78 of the bracket 54. Further, the chamfered flanges 156 are also generally aligned with the chamfers 88 and 104 of the end wedges 84 and 100, with the chamfers 88 and 104 accordingly providing clearance for seating and movement of the end wedges 84 and 100 within the retainer 50.

As the retainer 50 is moved to the expanded configuration (see, e.g., FIG. 15B), the shoulders 68 remain engaged with the flanges 154, while the ramped surfaces 78 are moved into engagement with the chamfered flanges 156. Accordingly, the covers 56 and 58 can help to hold the retainer 50 together, while also permitting the brackets 52 and 54 to move relative to each other (e.g., via absolute movement of a single one of the brackets 52 and 54, from a perspective that is fixed relative to the other of the brackets 52 and 54).

In some embodiments, lateral expansion of the retainer 50 can also correspond to a shifting of the rod actuator 60 towards the chamfered flanges 156. This shifting, in some embodiments, can be facilitated by the elongate openings 152 on the covers 56 and 58 (see, e.g., FIGS. 10A through 10E), which can allow the rod actuator 60 to move laterally relative to the covers 56 and 58 while still remaining appropriately engaged with the covers 56 and 58 and with the remainder of the retainer 50.

In some embodiments, to provide relatively low resistance to heat transfer and/or to provide a relatively small profile for the retainer 50, various wedges of the retainer 50, such as the expansion wedges 126 and 134, can be seated in close contact with the brackets 52 and 54, whether the retainer 50 is in the relaxed configuration or the expanded configuration. For example, as illustrated in FIG. 16A, in the relaxed configuration, the ramped outer surfaces 124a and 144b of the expansion wedges 126 and 134 (as well as other wedges, not shown in FIG. 16A) can be seated substantially fully against the ramped inner walls 72a, 72b, 80a, and 80b of the channels 66 and 76 of the brackets 52 and 54, with chamfered corners of the expansion wedges 126 and 134 (and other wedges) seated on the flat bottoms 66a and 76a of the angled channels 66 and 76. Accordingly, in the relaxed configuration, the various wedges (e.g., the expansion wedges 126 and 134) and the brackets 52 and 54, as well as the rod actuator 60 and/or other components, can allow for lateral conductive heat transfer over almost the entire internal area of the retainer 50.

As also described above, through an initial rotation of the rod actuator 60 (or other actuation), the retainer 50 can be moved from the relaxed configuration of FIG. 16A into an expanded configuration, such as the example intermediate expanded configuration illustrated in FIG. 16B. In particular, as also noted above, as the expansion wedges 126 and 134 are moved laterally (i.e., vertically, from the perspective of FIG. 16B), the ramped outer surfaces 124a and 144b of the expansion wedges 126 and 134 bear on the ramped inner walls 72a, 72b, 80a, and 80b of the angled channels 66 and 76, thereby causing the brackets 52 and 54 to also move laterally outward, but in directions that are different from (e.g., generally perpendicular to) the lateral movement of the expansion wedges 126 and 134 (e.g., to the right and left, from the perspective of FIG. 16B).

In the intermediate expanded configuration illustrated in FIG. 16B, the retainer 50 may apply significant clamping force, but may not yet be disposed to apply maximum clamping force because the expansion wedges 126 and 134 can still be moved further in the vertical direction to urge the brackets 52 and 54 further outward away from the rod actuator 60. However, the ramped outer surfaces 124a and 144b of the various expansion wedges 126 and 134 remain in substantially full (or near-full) contact with the angled walls of the channels 66 and 76. Further, as illustrated in FIG. 15B, the ramped surfaces 128a, 130a, 138b, and 140b of the expansion wedges 126 and 134 remain in substantial contact with the associated ramped surfaces of adjacent wedges (e.g., the ramped surfaces 86a, 86b, 102a, 102b, 116a, 116b, 118a, and/or 118b). Usefully, this relatively substantial contact between the various surfaces can allow for relatively significant conductive heat transfer between the brackets 52 and 54 and the expansion wedges 126 and 134, as well as generally low thermal resistance for conductive heat transfer through the retainer 50 as a whole.

If more significant clamping is desired, the rod actuator 60 can be rotated further, thereby moving the retainer 50 into a more fully expanded configuration, as illustrated in FIG. 16C. In the more fully expanded configuration illustrated in FIG. 16C, the retainer 50 may apply somewhat more clamping force than in the configuration illustrated in FIG. 16B, while still providing relatively low thermal resistance for conductive heat transfer. However, due to the additional lateral expansion of the wedge arrangement relative to the configuration illustrated in FIG. 16B, the various expansion wedges 126 and 134 may exhibit somewhat less contact with the internal walls of the angled channels 66 and 76, with correspondingly greater thermal resistance for conductive heat transfer through the retainer 50 generally.

In this light of the discussion above, the retainer 50 can usefully allow a user to select an optimal expanded configuration, in which an appropriate balance is struck between clamping force and conductive thermal resistance. For certain applications, for example, an intermediate expanded configuration as in FIG. 16B may be useful, in order to provide near-minimal thermal resistance for conductive heat transfer along with appropriate, but not maximized, clamping force. Likewise, for other applications, a more fully expanded configuration as in FIG. 16C may be selected, in order to provide near-maximal clamping force along with significant, but not minimized thermal resistance.

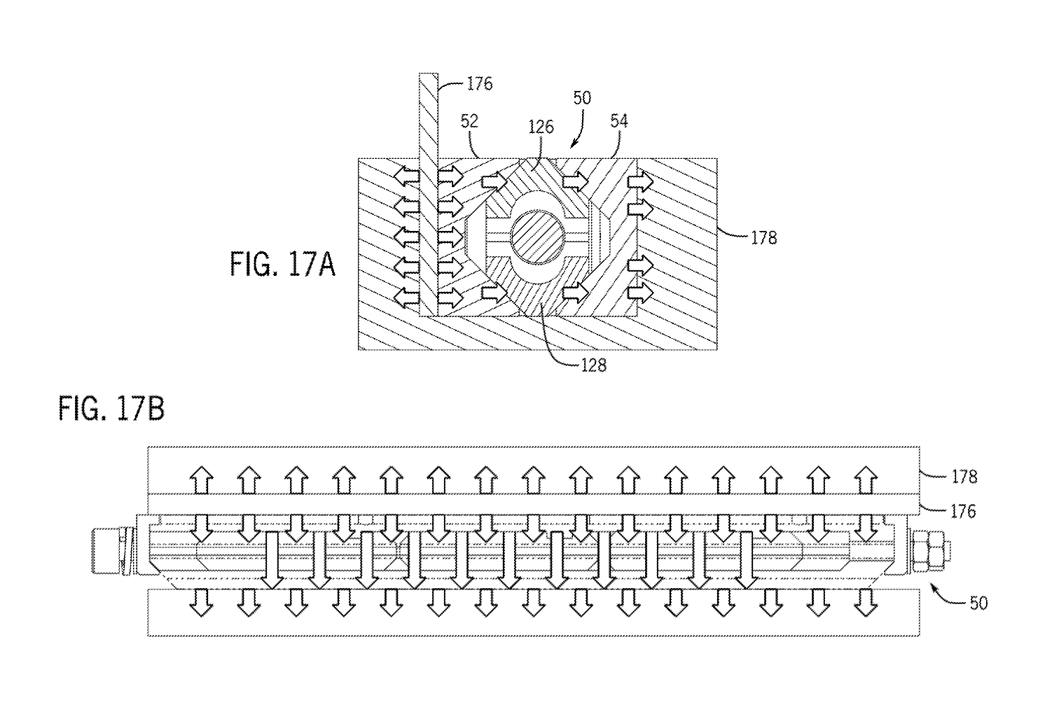

FIGS. 17A and 17B illustrate the retainer 50 securing a PCB 176 within a channel of a cold plate 178. As also discussed above, contact between various components of the retainer 50, such as between the various expansion wedges 126 and 134 and the brackets 52 and 54 and other wedges, can provide the retainer 50 with relatively low thermal resistance, even when the retainer 50 is in an expanded (e.g., partly or fully expanded) configuration. Accordingly, as illustrated by the various block arrows of FIGS. 17A and 17B, heat transfer from the PCB 176 through the retainer 50 can remove substantial thermal energy from the PCB 176, including potentially as much or more thermal energy as is transferred directly from the PCB 176 to the cold plate 178. In some embodiments, a retainer according to the invention can accordingly provide a notable improvement in general thermal performance as compared to conventional retainers (see, e.g., FIGS. 1 and 2). For example, in some embodiments, contact area between internal components of the retainer 50, as can facilitate conductive heat flow through the retainer 50, can be up to four times greater than in conventional retainers, with correspondingly significant improvement in conductive heat transfer performance.

In some embodiments, biased configurations for a wedge arrangement are possible. For example, in some embodiments, a wedge arrangement can be biased towards an expanded configuration. This can be useful, for example, so that the relevant retainer can hold itself in place relative to a body (e.g., within a channel of a cold plate), even before an actuator of the retainer is used to compress the wedge arrangement.

As illustrated in FIGS. 18A through 19B, for example, in some arrangements of the retainer 50, a spring element 182 (e.g., a coil spring) is installed within the countersunk portion 94 of the bore 92 through the end wedge 84 (see also FIGS. 3A through 3F), and is captured and retained within the bore 92 by the cover 56. Thus arranged, the spring element 182 biases the end wedge 84 away from the cover 56, thereby biasing the retainer 50 towards the expanded configuration (see FIGS. 18B and 19B). Thus, to install the retainer 50, the spring element 182 can be compressed via manual compression of the brackets 52 and 54 towards each other, then moved into the desired position, such as within a channel of a cold plate. To more firmly secure the retainer 50 in the expanded configuration, the rod actuator 60 can then be rotated, thereby compressing the wedge arrangement, as discussed above, with any additional movement of the end wedge 84 towards the cover 56 (e.g., as driven by movement of the end wedge 100 towards the end wedge 84) further compressing the spring element 182 within the bore 92 (see FIGS. 18A and 19A).

In some embodiments, a retainer according to the invention can hold together as an integral assembly even when not installed on or with a PCB or other relevant structure. For example, in the retainer 50, as also discussed above, the rod actuator 60 extends longitudinally beyond both of the covers 56 and 58, with various expanded-diameter features, such as washers, nuts, c-clips, hex sockets, and so on, preventing the rod actuator 60 from being longitudinally withdrawn from the assembly. Due to the extension of the rod actuator 60 through the various wedges 84, 100, 114, 126, and 134, as well as the engagement of the covers 56 and 58 with the brackets 52 and 54 and with the covers 56 and 58, the retainer 50 is accordingly securely held together even when not secured to an electronic module or within a channel.

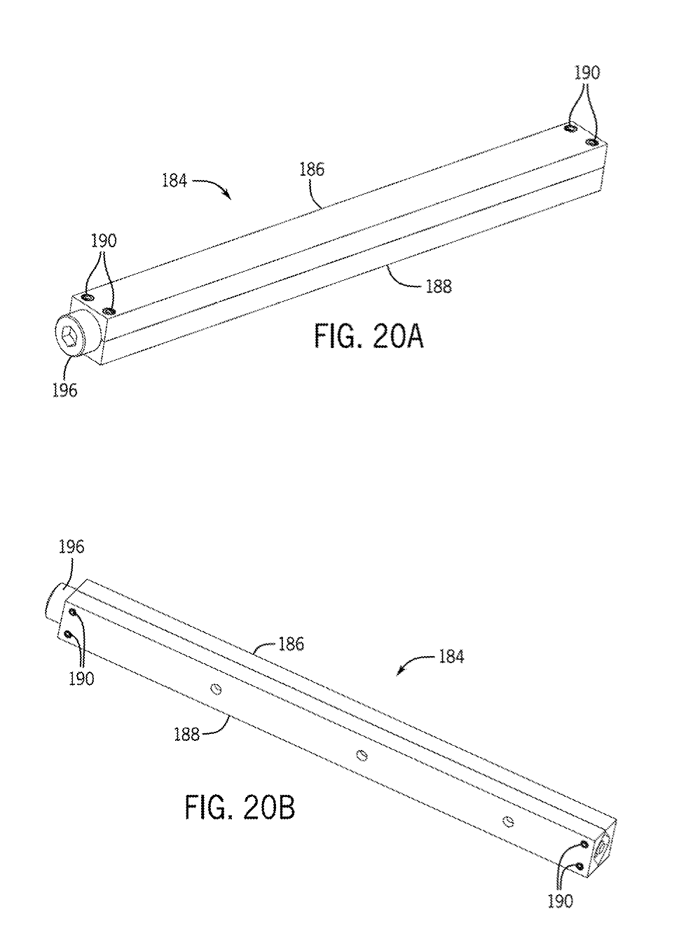

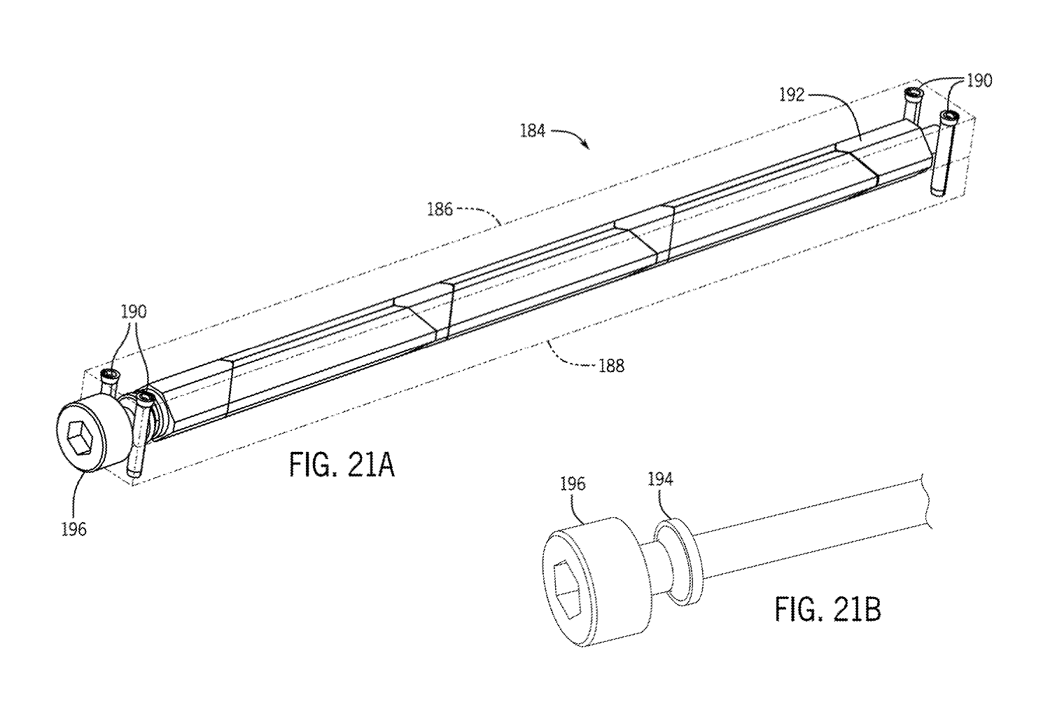

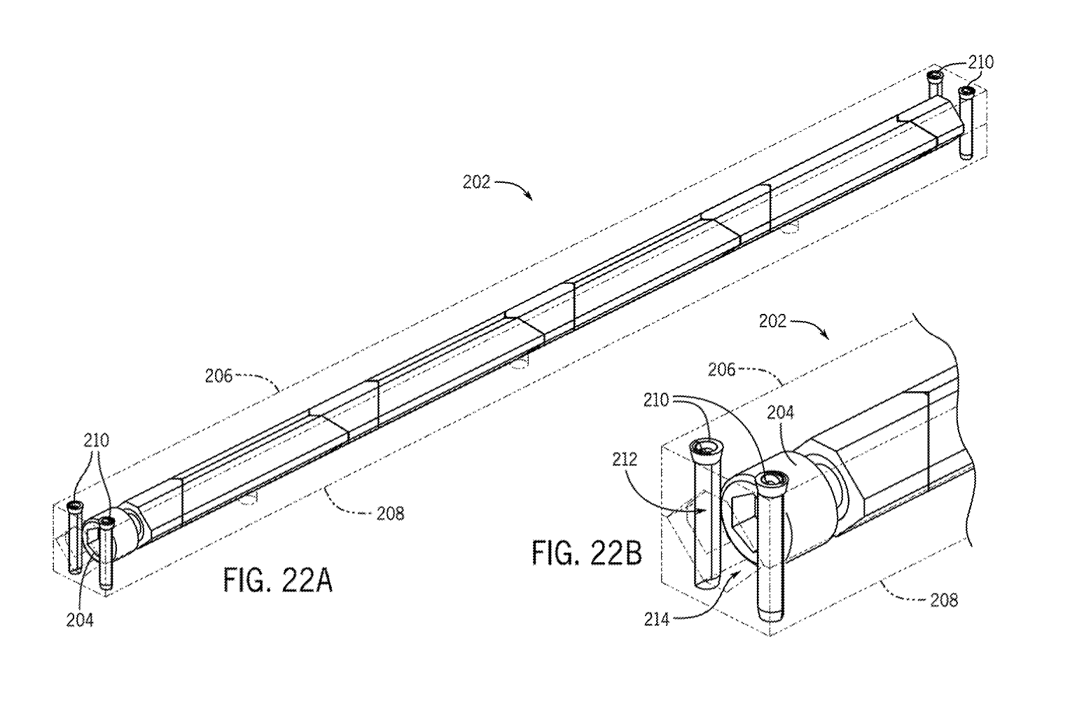

In other embodiments, other configurations are possible. In some embodiments, pins can be employed to secure together the brackets and the retainer generally (e.g., instead of covers). As illustrated in FIGS. 20A, 20B and 21A, for example, a retainer 184 according to an embodiment of the invention includes a set of brackets 186 and 188 that are secured together by pins 190 (e.g., tapered spiral pins). Generally, the brackets 186 and 188 can be separated from each other similarly to the brackets 52 and 54 discussed above, in order to secure electronic modules in place, with one or both of the brackets 186 and 188 being configured to slide relative to the pins 190 in order for the retainer 184 as a whole to expand.

At one end of the retainer 184, as illustrated in FIG. 21A in particular, an end wedge 192 can be longitudinally retained within the brackets 186 and 188 by a pair of the pins 190. At an opposite end, as illustrated in FIGS. 21A and 21B, a collar 194 on a rod actuator 196 can be similarly retained by another pair of the pins 190 in order to secure the rod actuator 196 within the retainer 184, while allowing the head of the actuator 196 to extend outside of the brackets 186 and 188 for easy access. With this configuration, in contrast to the illustrated configuration of the retainer 50 (see, e.g., FIGS. 3A through 3F), the brackets 186 and 188 can engage relevant surfaces (e.g., of a PCB and a cold plate) along almost the entire length of the retainer 184, except for the length of the hex socket portion of the rod actuator 196.

FIGS. 22A and 22B illustrate another retainer 202 according to an embodiment of the invention, which is configured generally similarly to the retainer 184 of FIGS. 20A through 21A. In contrast to the retainer 184, however, a rod actuator 204 of the retainer 202 is retained longitudinally within a set of brackets 206 and 208 by a set of pins 210, with no part of the rod actuator 204 extending longitudinally beyond the brackets 206 and 208. Rather, access to actuate the rod actuator 204 is provided via the open longitudinal ends of angled channels 212 and 214 of the brackets 206 and 208. With this configuration, the brackets 206 and 208 can accordingly engage relevant surfaces (e.g., of a PCB and a cold plate) along the entire length of the retainer 202.

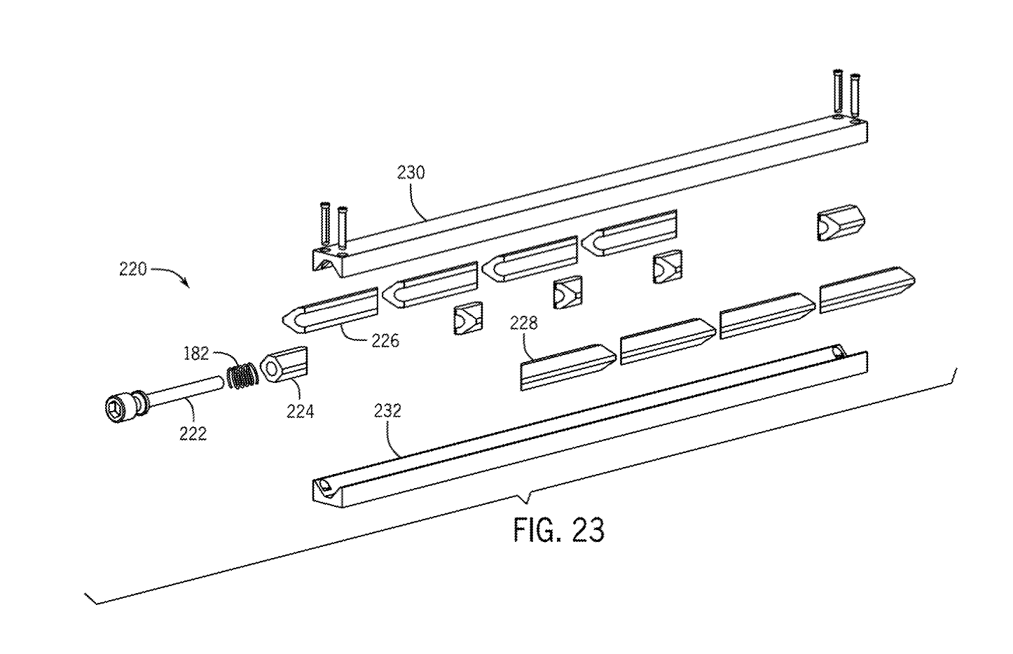

In some embodiments, a rod (or other) actuator may extend only partly through a wedge assembly of a retainer or may not extend into a wedge assembly at all. For example, a retainer 220 according to an embodiment of the invention is illustrated in FIG. 23. Generally, the retainer 220 is configured similarly to the retainers 184 and 202 of FIGS. 20A through 22B. In contrast to the retainers 184 and 202, however, the retainer 220 includes a relatively short rod actuator 222. In the embodiment illustrated, for example, the rod actuator 222 is configured to extend longitudinally only through a threaded bore of an end wedge 224 and through part of a first set of expansion wedges 226 and 228, rather than along the entire longitudinal length of the wedge arrangement or of the retainer 220, generally. In this regard, the end wedge 224 can be moved, and the wedge assembly compressed or relaxed due to the interaction of the rod actuator 222 with the threaded bore of the end wedge 224, when the rod actuator 222 is rotated. In particular, the rod actuator 222 can be rotated in a particular direction order to move the end wedge 224 into the retainer 220, thereby longitudinally compressing the wedge arrangement, similarly to the expansion of other wedge arrangements discussed herein, in order to expand brackets 230 and 232 laterally outward. In other embodiments, other configurations are possible. For example, a rod actuator similar to the rod actuator 222 may be configured to be fully enclosed by brackets, such as the rod actuator 204 of FIGS. 22A and 22B.

In some embodiments, as also noted above, bores may not extend fully through one or more wedges of a wedge assembly. For example, in some configurations, the various wedges of the retainer 220 (except, for example, the end wedge 224 and, potentially, part or all of the first set of expansion wedges 226 and 228) can be formed without bores (or half-bores or other grooves) extending therethrough. In this way, for example, the retainer 220 can still be moved into the expanded configuration by rotation of the rod actuator 222, while the lack of bores through the various wedges can further increase the area for conductive heat transfer through the retainer 220.

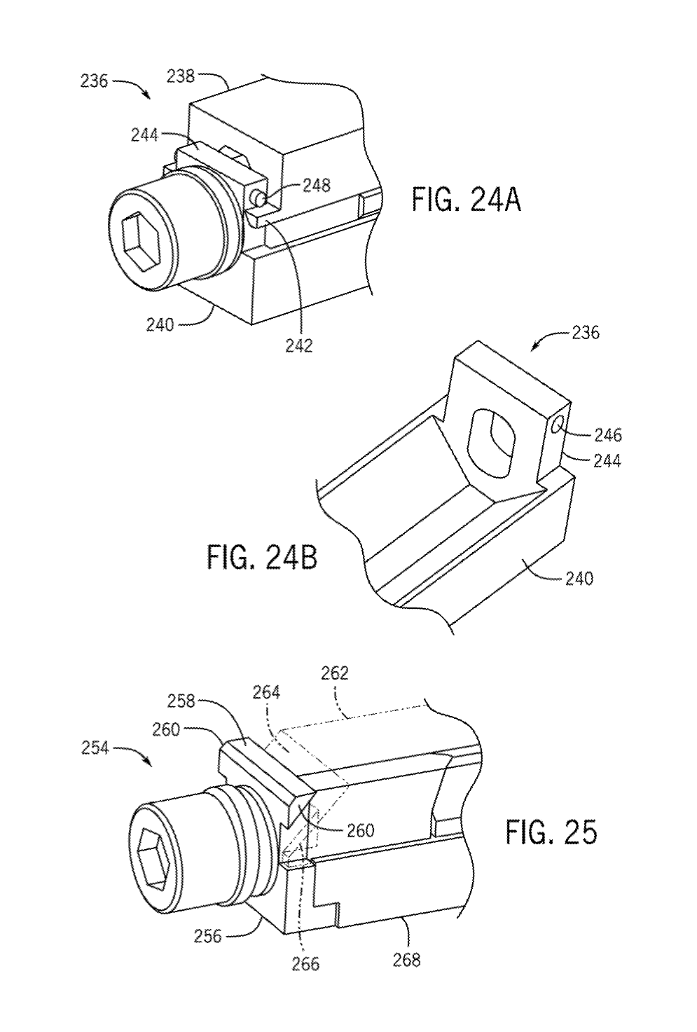

FIGS. 24A and 24B illustrate components of a retainer 236 according to another embodiment of the invention. Generally, the retainer 236 is similar to the retainer 50 (see, e.g., FIGS. 3A through 3F). However, the retainer 236 does not include a cover similar to the cover 56. Further, a set of brackets 238 and 240 for the retainer 236 are configured somewhat differently from the brackets 52 and 54 of the retainer 50. As illustrated in FIG. 24A, for example, the bracket 238 is configured with a set of peg-like protrusions 242 (only one shown) at one longitudinal end. As illustrated in FIG. 24B, the bracket 240 correspondingly includes an extended end wall 244 with a narrower lateral width than the remainder of the bracket 240, and with openings 246 for a protruding pin 248 (see FIG. 24A) or pins (not shown). With the retainer 236 fully assembled, the protrusions 242 can slide along opposite sides of the extended end wall 244 over a range that is bounded by the remainder of the bracket 240 and by the protruding portions of the pin 248 (or pins), thereby allowing the bracket 240 to move relative to the bracket 238 (e.g., to secure a PCB to a cold plate). In some embodiments, other configurations are possible. For example, the pin 248 (or pins) can be replaced with an integral or other protrusion from the extended end wall 244.

FIG. 25 illustrates components of a retainer 254 according to still another embodiment of the invention. Generally, the retainer 254 is similar to the retainer 50 (see, e.g., FIGS. 3A through 3F). However, a cover 256 for the retainer 254 is configured somewhat differently from the cover 56 of the retainer 50. In the embodiment illustrated in FIG. 25, the cover 256 includes an extended end wall 258, with a generally narrower lateral width than the remainder of the cover 256, and with a pair of transversely-extending chamfered protrusions 260 at one end. A bracket 262 configured for use with the cover 256 is also configured somewhat differently than, for example, the bracket 54. For example, in the embodiment illustrated, the bracket 262 includes a ramped surface 264 at a longitudinal end thereof, with a central cut-out that defines a pair of ramped protrusions 266 (only one shown).

With the retainer 254 fully assembled, the ramped protrusions 266 can slide along opposite sides of the extended end wall 258 over a range that is bounded by the remainder of the cover 256 and by the chamfered protrusions 260, thereby allowing the bracket 262 to move away from an opposing bracket 268. In this regard, for example, the operation of the retainer 254 at the cover 256 is generally similar to the operation of the retainer 236 at the ends of the brackets 238 and 240, as illustrated in FIGS. 24A and 24B. Correspondingly, in some embodiments, it may be possible to configure a cover and a bracket to be similar to the cover 256, but with non-ramped protrusions similar to those illustrated in FIGS. 24A and 24B.

In other embodiments, other configurations are possible. For example, separate rod (or other) actuators and corresponding engagement features (e.g., threading) of relevant wedges can be provided at opposite ends of a retainer, so that the retainer can be expanded or relaxed by a user engaging one or both ends of the retainer. Likewise, various combinations of thread types on rod actuators and wedges of a wedge arrangement in order to allow for expansion or relaxation of a retainer based on a variety of different rotational inputs (e.g., compression via right-hand rotation or via left-hand rotation). Further, various combinations and permutations of features discussed above can be employed in various embodiments. For example, specific configurations of the covers, brackets, actuators, and so on, as expressly discussed above, can be used in various combinations in different embodiments.

Thus, embodiments of the disclosure provide for retainers with generally improved retention of electronic modules, including improved conductive heat transfer through the various retainers, as compared to conventional designs. Usefully, the modularity of some embodiments (e.g., the interchangeability and interoperability of the various end, center, and expansion wedges) can allow a user to assemble a retainer with any variety of dimensions, including retainers with customizable lengths and expansion distances. Embodiments of the disclosed brackets for securing retainers to electronic modules can also provide for customizable configurations. For example, because certain brackets can be configured to extend over all (or substantially all) of the longitudinal length of the relevant retainers, mounting holes to secure the electronic modules to the relevant brackets can be placed at any variety of positions along the brackets. Additionally, due to the disclosed combination of internal wedges and external brackets, embodiments of the disclosed retainer can be actuated to and from expanded configurations without subjecting the associated electronic modules (or structures to which the modules are secured) to significant axial loading.

The previous description of the disclosed embodiments is provided to enable any person skilled in the art to make or use the invention. Various modifications to these embodiments will be readily apparent to those skilled in the art, and the generic principles defined herein may be applied to other embodiments without departing from the spirit or scope of the invention. Thus, the invention is not intended to be limited to the embodiments shown herein but is to be accorded the widest scope consistent with the principles and novel features disclosed herein.

1. A retainer configured to secure an electronic module within a channel, the retainer comprising:
a wedge arrangement that extends along a wedge axis and includes a plurality of actuation wedges, a first expansion wedge, and a second expansion wedge;
an actuator configured to compress the plurality of actuation wedges along the wedge axis; and
a first bracket and a second bracket, each secured at least partly around the wedge arrangement;
the actuation wedges being configured, when the actuation wedges are compressed along the wedge axis:
to urge the first expansion wedge in a first expansion direction that is substantially perpendicular to the wedge axis; and
to urge the second expansion wedge in a second expansion direction that is substantially opposite the first expansion direction; and
the first and second expansion wedges being configured, when urged, respectively, in the first and second expansion directions:
to collectively urge the first bracket in a first clamping direction that is substantially perpendicular to the first expansion direction and to the wedge axis; and
to collectively urge the second bracket in a second clamping direction that is substantially opposite the first clamping direction, to secure the electronic module within the channel.

2. The retainer of claim 1, with the electronic module and a wall of the channel being spaced apart from each other along a separation direction when the electronic module is within the channel, wherein the first expansion direction is substantially perpendicular to the separation direction.

3. The retainer of claim 1, wherein the first and second expansion wedges are disposed on opposite sides of the wedge axis from each other.

4. The retainer of claim 1, wherein the actuation wedges include a first actuation wedge and a second actuation wedge;
wherein the first actuation wedge includes a first bidirectional ramp configured to engage a first end of each of the first and second expansion wedges, to urge the first and second expansion wedges in the first and second expansion directions, respectively; and
wherein the second actuation wedge includes a second bidirectional ramp configured to engage a second end of each of the first and second expansion wedges, to urge the first and second expansion wedges in the first and second expansion directions, respectively.

5. The retainer of claim 4, wherein the first actuation wedge is configured as an end wedge and the second actuation wedge is configured as a center wedge.

6. The retainer of claim 5, further comprising a third expansion wedge and a fourth expansion wedge;
wherein the center wedge further includes a third bidirectional ramp configured to engage a first end of each of the third and fourth expansion wedges, to urge the third and fourth expansion wedges in the first and second expansion directions, respectively, when the actuation wedges are compressed along the wedge axis.

7. The retainer of claim 1, wherein a first outer surface of the first expansion wedge and a first outer surface of the second expansion wedge engage an inner channel of the first bracket to urge the first bracket in the first clamping direction, when the first and second expansion wedges are urged in the first and second expansion directions, respectively.

8. The retainer of claim 7, wherein the first outer surface of the first expansion wedge engages a first angled wall of the inner channel of the first bracket to urge the first bracket in the first clamping direction; and
wherein the first outer surface of the second expansion wedge engages a second angled wall of the inner channel of the first bracket to urge the first bracket in the first clamping direction.

9. The retainer of claim 7, wherein a second outer surface of the first expansion wedge and a second outer surface of the second expansion wedge engage an inner channel of the second bracket to urge the second bracket in the second clamping direction.

10. The retainer of claim 1, further comprising:
a first cover engaging a respective first end of each of the first bracket and the second bracket to secure the first and second brackets around the wedge arrangement; and
a second cover engaging a respective second end of each of the first bracket and the second bracket to secure the first and second brackets around the wedge arrangement.

11. The retainer of claim 10, wherein at least one of the first and second covers is configured to move laterally relative to the wedge axis when the actuation wedges are compressed along the wedge axis.

12. A retainer for securing an electronic module to a body, the retainer having an elongate direction and comprising:
a first bracket and a second bracket;
a wedge arrangement that extends along a wedge axis in the elongate direction, is at least partly surrounded by the first and second brackets, and includes a first actuation wedge, a second actuation wedge, a first expansion wedge with opposite ramped ends, and a second expansion wedge with opposite ramped ends; and
an actuator configured to apply compressive force along the wedge axis to compress the wedge arrangement along the wedge axis
the first and second expansion wedges being disposed between the first and second actuation wedges, on opposite sides of the wedge axis relative to each other, with a respective first ramped end of each of the first and second expansion wedges engaging the first actuation wedge and with a respective second ramped end of each of the first and second expansion wedges engaging the second actuation wedge;
the actuator and the wedge arrangement being configured so that the compressive force urges the first and second actuation wedges, respectively, into the first and second ramped ends of the first and second expansion wedges to move the first and second actuation wedges in opposite lateral directions away from the wedge axis; and
the wedge arrangement and the first and second brackets being configured so that the lateral movement of the first and second actuation wedges away from the wedge axis urges the first and second brackets in opposite lateral directions away from the wedge axis, to move the first and second brackets, relative to the wedge axis, substantially perpendicularly to the lateral movement of the first and second actuation wedges away from the wedge axis.

13. The retainer of claim 12, wherein the first actuation wedge includes a first bidirectional ramp configured to engage the first ramped ends of the first and second actuation wedges; and
wherein the second actuation wedge includes a second bidirectional ramp configured to engage the second ramped ends of the first and second actuation wedges.

14. The retainer of claim 12, wherein the actuator is a rod actuator configured to apply compressive force to the wedge arrangement via rotation of the rod actuator.

15. The retainer of claim 14, wherein the rod actuator includes a single threaded rod that extends through the wedge arrangement along the wedge axis, with the rod actuator extending through a first groove on an inner side of the first expansion wedge and a second groove on an inner side of the second expansion wedge.

16. The retainer of claim 12, wherein of a first outer surface of the first expansion wedge and a first outer surface of the second expansion wedge engage an inner channel of the first bracket to urge the first bracket away from the wedge axis.

17. The retainer of claim 16, wherein the first outer surface of the first expansion wedge is a ramped surface and engages a first ramped wall of the inner channel of the first bracket to urge the first bracket away from the wedge axis; and
wherein, the first outer surface of the second expansion wedge is a ramped surface and engages a second ramped wall of the inner channel of the first bracket to urge the first bracket away from the wedge axis.

18. The retainer of claim 16, wherein a second outer surface of the first expansion wedge and a second outer surface of the second expansion wedge engage an inner channel of the second bracket to urge the second bracket away from the wedge axis.

19. The retainer of claim 12, further comprising:
a first cover engaging a respective first end of each of the first bracket and the second bracket to secure the first and second brackets around the wedge arrangement; and
a second cover engaging a respective second end of each of the first bracket and the second bracket to secure the first and second brackets around the wedge arrangement.

20. A method of securing an electronic module to a body with a channel, the method comprising:
disposing a retainer within the channel, the retainer including a wedge arrangement that extends along a wedge axis and at least two brackets that at least partly surround the wedge arrangement, and the wedge arrangement including:
at least two expansion wedges disposed on opposite sides of the wedge axis relative to each other; and
actuation wedges configured as two or more of: a first end wedge, a second end wedge, and a center wedge; and
applying a compressive force to move the actuation wedges along the wedge axis, so that ramped surfaces of the actuation wedges are urged against ramped surfaces of the expansion wedges to urge the actuation wedges in first opposite lateral directions, relative to the wedge axis, the actuation wedges thereby urging the at least two brackets in second opposite lateral directions that are substantially perpendicular to the first opposite lateral directions, to clamp the body within the channel.
